(19) United States
(12) Patent Application Publication
(10) Pub. No.: US 2023/0352634 A1
(43) Pub. Date: Nov. 2, 2023

(54) SEMICONDUCTOR LIGHT EMITTING ELEMENT CHIP INTEGRATED DEVICE AND MANUFACTURING METHOD THEREOF

(71) Applicant: ULDTEC CO., LTD., Sendai-shi (JP)

(72) Inventor: Motonobu TAKEYA, Sendai-shi (JP)

(21) Appl. No.: 17/928,508

(22) PCT Filed: Jun. 15, 2021
(86) PCT No.: PCT/JP2021/022603

§ 371 Date: Nov. 29, 2022

(30) Foreign Application Priority Data
Sep. 16, 2020 (JP) 2020-155201
Sep. 24, 2020 (JP) 2020-159225

(51) Int. Cl. H01L 33/48; H01L 25/075; H01L 33/42; H01L 33/62

(52) U.S. Cl. CPC H01L 33/486; H01L 25/0753; H01L 33/42; H01L 33/62; H01L 2933/0016

(57) ABSTRACT

The semiconductor light emitting element chip integrated device has a mounting substrate 100 having a lower electrode 120 on one major surface, a chip joining part formed by a part of the upper surface of the lower electrode 120 and the like, a vertical semiconductor light emitting element chip 10 having a plurality of p-side electrodes 17 and an n-side electrode on the upper surface and the lower surface joined to the chip joining part and an upper electrode 140 as the upper layer of the vertical semiconductor light emitting element chip having an upper electrode main line part 141 and a plurality of upper electrode branch line parts 142 which are connected each other by a thin film fuse 143. The semiconductor light emitting element chip 10 is joined to the chip joining part such that the n-side electrode faces the chip joining part. The n-side electrode and the lower electrode 120 are electrically connected each other. At least one of the p-side electrodes 17 and the upper electrode branch line parts 142 of the upper electrode 140 are electrically connected each other.

### TECHNICAL FIELD

The present invention relates to a semiconductor light emitting element chip integrated device and manufacturing method thereof which are suitably applied to, for example, a micro LED display in which a number of small-sized longitudinal (or vertical) or lateral micro light emitting diode (LED) chips are integrated on a substrate.

### BACKGROUND ART

At present, the mainstream of displays such as thin type televisions, smartphones and the like are liquid crystal displays (LCDs) and organic EL displays (OLEDs). Regarding LCDs, the output light quantity is about one tenth of the light quantity of the backlight as pixels become small. Regarding OLEDs, although theoretical power efficiency is high, the output light quantity of real products remains in level equal to LCDs.

Micro LED displays receive attention as displays having high luminance and high efficiency (low power consumption) far surpassing LCDs and OLEDs. Direct light emission micro LED displays have high efficiency. However, in order to realize micro LED displays, it is necessary to arrange several tens million micro LED chips having the size of order of several μm to tens of μm.

As methods for arranging such a large number of micro LED chips on a mounting substrate, proposed conventionally have been a method using a chip sorter, a method using a multichip transfer device (see patent literatures 1 and 2), a chip arranging method using chip ejection by laser irradiation and a liquid (see patent literature 3), a device (chip) arranging method using a magnetic film (see patent literatures 4 and 5) and the like.

However, according to the methods proposed in the patent literatures 1-5, it has been difficult to realize micro LED displays at low cost.

Against the background described above, present inventor has proposed a method of manufacturing a semiconductor chip integrated device which can realize the micro LED display at low cost (see patent literature 6). According to the patent literature 6, the micro LED display is manufactured by ejecting an ink in which micro LED chips, each of which is configured such that the p-side electrode side is more strongly attracted to a magnetic field than the n-side electrode side, for example, are dispersed in a liquid to a chip joining part on one major surface of a substrate and joining the p-side electrode side of the micro LED chips to the chip joining part by applying an external magnetic field to the substrate from below it.

On the other hand, in order to repair LED displays, there has been proposed a panel structure having redundancy scheme which can mount a plurality of LED chips in one subpixel (see patent literature 7). There has been also proposed a display device in which particle-like light emitting diodes are scattered in pixels and fuse parts which conduction is broken off by overcurrent are provided for repairing defective pixels (see patent literature 8).

### PRIOR ART LITERATURE

### Patent Literature

[PATENT LITERATURE 1] Laid-open publication No. 2017-531915
[PATENT LITERATURE 2] Laid-open publication No. 2017-500757
[PATENT LITERATURE 3] Laid-open publication No. 2005-174979
[PATENT LITERATURE 4] Laid-open publication No. 2003-216052
[PATENT LITERATURE 5] Laid-open publication No. 2016-25205
[PATENT LITERATURE 6] Patent Gazette No. 6694222
[PATENT LITERATURE 7] Laid-open publication No. 2016-512347
[PATENT LITERATURE 8] Laid-open publication No. 2010-87452

### SUMMARY OF INVENTION

### Subjects to be Solved by Invention

According to the method of manufacturing a micro LED display described in the patent literature 6, it is possible to realize micro LED displays at low cost. However, when defection of micro LED chips is found by a test, it is not always easy to repair the micro LED display. Therefore, there is still room for improvement.

According to the method described in the patent literature 7, cost of materials of LED chips increases greatly by adopting redundancy scheme and this invites an obstacle to reduce cost. According to the method described in the patent literature 8, it is difficult to control step for etching semiconductor layers of the particle-like light emitting diodes and therefore it is difficult to put the method to practical use.

Therefore, the subject to be solved by the invention is to provide a semiconductor light emitting element chip integrated device and manufacturing method thereof which can manufacture various semiconductor light emitting element chip integrated devices such as micro LED displays and the like by using a multichip transfer method and the like and which can easily repair the semiconductor light emitting element chip integrated device when defection such as leakage defection and the like of semiconductor light emitting element chips such as micro LED chips and the like is found after the semiconductor light emitting element chips are mounted on a substrate.

### Means to Solve the Subjects

In order to solve the subject, according to the invention, there is provided a semiconductor light emitting element chip integrated device, comprising:
a substrate having a lower electrode on one major surface,
a chip joining part which is formed by a part of the upper surface or a protrusion or a concavity provided on a part of the upper surface of the lower electrode,
a vertical semiconductor light emitting element chip having a plurality of p-side electrodes and an n-side electrode on the upper surface and the lower surface joined to the chip joining part; and
an upper electrode as the upper layer of the semiconductor light emitting element chip having a main line part and a plurality of branch line parts which are connected each other by a thin film fuse or directly connected each other,
the semiconductor light emitting element chip being joined to the chip joining part such that the n-side electrode faces the chip joining part, the n-side electrode and the lower electrode being electrically connected each other and at least one of the p-side electrodes of the semiconductor light emitting element chip and the branch line parts of the upper electrode being electrically connected each other.

The substrate (or mounting substrate) is not limited and may be, for example, a Si substrate, a glass substrate, a glass epoxy substrate, a resin film, a printed circuit board and the like. The substrate may be rigid or flexible and transparent or opaque and may be selected as necessary. Arranging patterns, sizes, planar shapes, intervals and the like of the chip joining parts formed on the upper surface of the lower electrode provided on one major surface of the substrate are selected as necessary depending on the size and planar shape of the semiconductor light emitting element chip to be mounted, uses of the semiconductor light emitting element chip integrated device, functions demanded for the semiconductor light emitting element chip integrated device and the like. In an example of arranging pattern of the chip joining parts of the substrate, the chip joining parts are formed in a two-dimensional array. The lower electrode serves as a wiring line for connecting the semiconductor light emitting element chips joined to the chip joining parts. The lower electrodes are provided in a predetermined pattern, arrangement and intervals.

The semiconductor light emitting element of the semiconductor light emitting element chip may include a light emitting diode (LED), a laser diode (LD) (especially, vertical cavity surface light emitting laser (VCSEL)), an organic EL element and the like. The semiconductor light emitting element may be an AlGaInN-based semiconductor light emitting element, an AlGaInP-based semiconductor light emitting element and the like, but not limited to these. The AlGaInN-based semiconductor light emitting element is used to obtain light emission of a wavelength band of bluepurple, blue to green (wavelength of 390 nm˜550 nm). The AlGaInP-based semiconductor light emitting element is used to obtain light emission of a wavelength band of red (wavelength of 600 nm˜650 nm) is obtained. The AlGaInN-based semiconductor light emitting element and phosphors may be combined to obtain a wavelength band of blue, green, red. The p-side electrodes and the n-side electrode of the semiconductor light emitting element chip may be formed by conventionally publicly known materials and the materials are selected as necessary. In a typical example, the semiconductor light emitting element chip is a gallium nitride (GaN)-based light emitting diode chip.

The p-side electrodes of the semiconductor light emitting element chip are typically provided in a line or a plurality of lines but not limited to this and a part or all of the p-side electrodes may be provided in irregular arrangement. The number of the p-side electrodes or the number of the lines and the number of the p-side electrodes in each line if the p-side electrodes are provided in a line or a plurality of lines are selected as necessary. For example, consider a case where the p-side electrodes are provided in a line or a plurality of lines. Assuming that the chip size is fixed, if the position of the semiconductor light emitting element chip for the chip joining part shifts, generally, a plurality of lines is more preferable than a line and more number of the semiconductor light emitting element chips in each line is more preferable to electrically connect the p-side electrodes of the semiconductor light emitting element chip and the branch line parts of the upper electrode surely.

The shape of the semiconductor light emitting element chip is typically rectangular, but not limited to this. Chip size of the semiconductor light emitting element chip is selected as necessary and is generally selected to be not larger than (30˜100) μm×(10˜50) μm. The thickness of the semiconductor light emitting element chip is also selected as necessary and is generally selected to be not larger than 100 μm. The semiconductor light emitting element chip is desired to be one produced by carrying out crystal growth of semiconductor layers forming the semiconductor light emitting element on a substrate and separating the substrate from the semiconductor layers and its thickness is not larger than 20 μm, for example.

The upper electrode formed as the upper layer of the semiconductor light emitting element chip has a plurality of branch line parts such that it straddles the chip joining part, preferably extends over almost all the area of the chip joining part. Regarding the branch line parts, the width of each branch line part is 5˜20 μm, the width of an opening between the branch line parts is 1˜10 μm and the number of the branch line parts is 3˜10. These numerals can be designed suitably depending on sizes of a circuit unit or a pixel containing the semiconductor light emitting element chip joined to the chip joining part, the area or shape of the chip joining part, chip size and the like. Typically, the branch line parts may be formed parallel to each other on the chip joining part and perpendicular to the main line part, but not limited to this. Each of the branch line parts may be generally electrically connected to at least one of the p-side electrodes included in the semiconductor light emitting element chip joined to the chip joining part. The main line part is typically formed to extend along the chip joining parts.

Materials, width, thickness, shape and the like of the thin film fuse which connects the main line part and the branch line parts are selected such that the thin film fuse can melt to be cut by applying a voltage for repair and supplying a predetermined current between the branch line parts of the upper electrode which are connected to the p-side electrodes of the semiconductor light emitting element chip and the lower electrode. If too much current is necessary to cut the thin film fuse, there is a possibility that thermal damage is caused to surrounding circuits due to the effects of Joule heat generated there. Taking into consideration thermal effects to the surrounding circuits, the thin film fuse is desired to be cut by a current of about several hundreds μA to several mA. In order to meet the conditions, the minimum value of the cross sectional area (width×thickness) of the thin film fuse is desired to be not larger than 0.5 μm², but not limited to this. The thin film fuse is made from metal having typically melting point not higher than 350° C. and typically melting point not lower than 150° C. As such metal exemplified are simple metal such as In, Sn and the like and alloy (eutectic alloy) such as InSn, InSnAg, AgSn, AgSn and the like, but not limited to this. If the main line part and the branch line parts are directly connected each other, a test voltage is applied between them such that the potential of the p-side electrodes becomes higher than that of the n-side electrode to make current flow through the p-side electrodes included in each semiconductor light emitting element chip. And image analysis of emission of light of each semiconductor light emitting element chip is carried out to find the branch line part with defection of light quantity due to leakage defection of the semiconductor light emitting element chip. Finally, the branch line part with defection of light quantity thus found is cut by laser beam irradiation and the like. In this way, the same result is obtained as cutting of the thin film fuse.

Typically, the substrate has a plurality of circuit units which can be independently driven and the lower electrode and the upper electrode are formed for each of the circuit units.

Especially, when the semiconductor light emitting element chip integrated device is a color display, one pixel is typically formed by an area including more than 3 circuit units adjacent to each other. The area of one pixel is typically selected to be about 500 μm×500 μm, but may be larger or smaller than 500 μm×500 μm. In this case, emission of three colors of red, green, blue is made possible by more than 3 circuit units.

If the semiconductor light emitting element chip integrated device is used as a backlight of the liquid display, it is possible to carryout very fine local dimming. In this case, a circuit unit may be formed in an area larger than several mm square.

The semiconductor light emitting element chip integrated device may be any and is suitably designed depending on kinds of semiconductor light emitting element chips. The semiconductor light emitting element chip integrated device may be a device in which a kind of semiconductor light emitting element chip is integrated, a device in which more than two kinds of semiconductor light emitting element chips are integrated or the devices combined with phosphor. The semiconductor light emitting element chip integrated device is, for example, a light emitting diode illumination device, a light emitting diode backlight, a light emitting diode display and the like, but not limited to these. Size, planar shape and the like of the semiconductor light emitting element chip integrated device are suitably selected depending on uses of the semiconductor light emitting element chip integrated device, functions demanded for the semiconductor light emitting element chip integrated device and the like.

There are various methods of taking out light from the semiconductor light emitting element chip integrated device. For example, each of the p-side electrodes and the branch line parts of the upper electrode is made of a transparent electrode and light emitted from the semiconductor light emitting element chip is transmitted through the p-side electrodes and the branch line parts of the upper electrode and taken out. Alternatively, each of the n-side electrode and a part of the lower electrode corresponding to the chip joining part is made of a transparent electrode and the substrate is transparent and light emitted from the semiconductor light emitting element chip is transmitted through the n-side electrode, the part of the lower electrode corresponding to the chip joining part and the substrate and taken out.

The semiconductor light emitting element chip is typically a gallium nitride-based semiconductor light emitting element chip. The semiconductor light emitting element chip may be an AlGaInP-based semiconductor light emitting element chip.

According to the invention, there is provided a semiconductor light emitting element chip integrated device, comprising:
a substrate having a lower electrode having a main line part and a plurality of branch line parts which are connected each other by a thin film fuse on one major surface,
a chip joining part which is formed by an area including at least a part of the upper surface of each of the branch line parts of the lower electrode,
a vertical semiconductor light emitting element chip having a plurality of p-side electrodes and an n-side electrode on the upper surface and the lower surface joined to the chip joining part; and
an upper electrode as the upper layer of the semiconductor light emitting element chip,
the semiconductor light emitting element chip being joined to the chip joining part such that the p-side electrodes face the chip joining part, at least one of the p-side electrodes and the branch line parts of the lower electrode being electrically connected each other and the n-side electrode of the semiconductor light emitting element chip and the upper electrode being electrically connected each other.

There are various methods of taking out light from the semiconductor light emitting element chip integrated device. For example, each of the n-side electrode and at least a part of the upper electrode which extends over the semiconductor light emitting element chip is made of a transparent electrode and light emitted from the semiconductor light emitting element chip is transmitted through the n-side electrode and the part of the upper electrode which extends over the semiconductor light emitting element chip and taken out. Alternatively, each of the p-side electrodes and the branch line parts of the lower electrode is made of a transparent electrode and the substrate is transparent and light emitted from the semiconductor light emitting element chip is transmitted through the p-side electrodes, the branch line parts of the lower electrode and the substrate and taken out.

In the invention of the semiconductor light emitting element chip integrated device, the explanation concerning the above invention of the semiconductor light emitting element chip integrated device comes into effect unless it is contrary to its character.

According to the invention, there is provided a semiconductor light emitting element chip integrated device, comprising:
a substrate having a lower electrode having a main line part and a plurality of branch line parts which are connected each other by a thin film fuse on one major surface,
an upper electrode as the upper layer of the lower electrode,
a chip joining part which is formed by an area including at least a part of the upper surface of each of the branch line parts of the lower electrode and a part of the upper surface of the upper electrode; and
a lateral semiconductor light emitting element chip having a plurality of p-side electrodes and an n-side electrode on one surface joined to the chip joining part,
the semiconductor light emitting element chip being joined to the chip joining part such that the p-side electrodes and the n-side electrode face the chip joining part, at least one of the p-side electrodes and the branch line parts of the lower electrode being electrically connected each other and the n-side electrode of the semiconductor light emitting element chip and the upper electrode being electrically connected each other.

There are various methods of taking out light from the semiconductor light emitting element chip integrated device. For example, light emitted from the semiconductor light emitting element chip is taken out to the side opposite to the substrate. Alternatively, each of the p-side electrodes and the branch line parts of the lower electrode is made of a transparent electrode and the substrate is transparent and light emitted from the semiconductor light emitting element chip is transmitted through the p-side electrodes, the branch line parts of the lower electrode and the substrate and taken out.

According to the invention, there is provided a semiconductor light emitting element chip integrated device, comprising:
a substrate having a lower electrode on one major surface,
an upper electrode as the upper layer of the lower electrode having a main line part and a plurality of branch line parts which are connected each other by a thin film fuse or directly connected each other,
a chip joining part which is formed by an area including at least a part of the upper surface of the lower electrode and at least a part of the upper surface of each of the branch line parts of the upper electrode; and
a lateral semiconductor light emitting element chip having a plurality of p-side electrodes and an n-side electrode on one surface joined to the chip joining part,
the semiconductor light emitting element chip being joined to the chip joining part such that the p-side electrodes and the n-side electrode face the chip joining part, at least one of the p-side electrodes and the branch line parts of the upper electrode being electrically connected each other and the n-side electrode of the semiconductor light emitting element chip and the lower electrode being electrically connected each other.

According to the invention, there is provided a method of manufacturing a semiconductor light emitting element chip integrated device, comprising steps of:
joining a vertical semiconductor light emitting element chip having a plurality of p-side electrodes and an n-side electrode on the upper surface and the lower surface to a chip joining part which is formed by a part of the upper surface or a protrusion or a concavity formed on a part of the upper surface of a lower electrode of a substrate having the lower electrode on one major surface such that the n-side electrode faces the chip joining part and electrically connecting the n-side electrode and the lower electrode each other; and
forming an upper electrode as the upper layer of the semiconductor light emitting element chip having a main line part and a plurality of branch line parts which are connected each other by a thin film fuse or directly connected each other such that at least one of the p-side electrodes of the semiconductor light emitting element chip and the branch line parts of the upper electrode is electrically connected each other.

The method of manufacturing a semiconductor light emitting element chip integrated device typically comprises further a step of making flow current by applying a voltage for repair between the branch line parts and the main line part after the upper electrode is formed. With this, if there occurs leakage defection and the like of the semiconductor light emitting element chip due to defects of the part of the p-side electrode and the like, the thin film fuse between the branch line part connected to the p-side electrode and the main line part can be cut, or a part of the branch line part can be cut. Therefore, it is possible to eliminate effects of defection and carry out repair. If there is no defection of the semiconductor light emitting element chip, it goes without saying that the thin film fuse is not cut, or a part of the branch line part is not cut.

Typically, the semiconductor light emitting element chip is joined to the chip joining part by multichip transfer methods, but not limited to this.

In the invention of the method of manufacturing a semiconductor light emitting element chip integrated device, other than the above, the explanation concerning the above invention of the semiconductor light emitting element chip integrated device comes into effect unless it is contrary to its character.

According to the invention, there is provided a method of manufacturing a semiconductor light emitting element chip integrated device, comprising steps of:
joining a vertical semiconductor light emitting element chip having a plurality of p-side electrodes and an n-side electrode on the upper surface and the lower surface to a chip joining part which is formed by an area including at least a part of the upper surface of each of branch line parts of a lower electrode of a substrate having a main line part and a plurality of branch line parts which are connected each other by a thin film fuse on one major surface such that the p-side electrodes face the chip joining part and electrically connecting at least one of the p-side electrodes and the branch line parts of the lower electrode each other; and
forming an upper electrode as the upper layer of the semiconductor light emitting element chip such that the n-side electrode of the semiconductor light emitting element chip and the upper electrode is electrically connected each other.

The method of manufacturing a semiconductor light emitting element chip integrated device differs from the method of manufacturing a semiconductor light emitting element chip integrated device described above in that the lower electrode, not the upper electrode, is formed to have a main line part and a plurality of branch line parts which are connected each other by a thin film fuse. As necessary, the upper electrode may also be formed to have a main line part and a plurality of branch line parts which are connected each other by a thin film fuse similarly to the lower electrode. In the invention of the method of manufacturing a semiconductor light emitting element chip integrated device, the explanation concerning the above invention of the semiconductor light emitting element chip integrated device comes into effect unless it is contrary to its character.

According to the invention, there is provided a method of manufacturing a semiconductor light emitting element chip integrated device, comprising steps of:
forming a lower electrode having a main line part and a plurality of branch line parts which are connected each other by a thin film fuse and an upper electrode as the upper layer of the lower electrode on one major surface of a substrate; and
joining a lateral semiconductor light emitting element chip having a plurality of p-side electrodes and an n-side electrode on one surface to a chip joining part which is formed by an area including at least apart of the upper surface of each of the branch line parts of the lower electrode and a part of the upper surface of the upper electrode such that the p-side electrodes and the n-side electrode face the chip joining part, electrically connecting at least one of the p-side electrodes and the branch line parts of the lower electrode each other and electrically connecting the n-side electrode and the upper electrode each other.

The method of manufacturing a semiconductor light emitting element chip integrated device typically comprises further a step of making flow current by applying a voltage for repair between the branch line parts and the main line part after the semiconductor light emitting element chip is joined to the chip joining part, at least one of the p-side electrodes and the branch line part of the lower electrode are electrically connected each other and the n-side electrode and the upper electrode are electrically connected each other.

In the invention of the method of manufacturing a semiconductor light emitting element chip integrated device, the explanation concerning each invention of the semiconductor light emitting element chip integrated device and the method of manufacturing thereof described above comes into effect unless it is contrary to its character.

According to the invention, there is provided a method of manufacturing a semiconductor light emitting element chip integrated device, comprising steps of:
forming a lower electrode and an upper electrode as the upper layer of the lower electrode having a main line part and a plurality of branch line parts which are connected each other by a thin film fuse or directly connected each other on one major surface of a substrate; and
joining a lateral semiconductor light emitting element chip having a plurality of p-side electrodes and an n-side electrode on one surface to a chip joining part which is formed by an area including at least a part of the upper surface of the lower electrode and at least a part of the upper surface of each of the branch line parts of the upper electrode such that the p-side electrodes and the n-side electrode face the chip joining part, electrically connecting the n-side electrode and the lower electrode each other and electrically connecting at least one of the p-side electrodes and the branch line part of the upper electrode each other.

In the invention of the method of manufacturing a semiconductor light emitting element chip integrated device, the explanation concerning each invention of the semiconductor light emitting element chip integrated device and the method of manufacturing thereof described above comes into effect unless it is contrary to its character.

### Effect of the Invention

According to the invention, the vertical or lateral semiconductor light emitting element chip having a plurality of p-side electrodes and an n-side electrode on the upper surface and the lower surface or on one surface is joined to the chip joining part provided on the upper surface of the branch line parts of the upper electrode or the lower electrode and the like and the semiconductor light emitting element chip is connected between the upper electrode and the lower electrode. Therefore, by applying a voltage for repair between the branch line parts and the main line part to make flow current, it is possible to cut the thin film fuse between the branch line part connected to the p-side electrode of the semiconductor light emitting element chip in which leakage defection and the like occur in the part of p-side electrodes and the like. Alternatively, it is possible to cut the branch line part which was found to be involved in defection by a test by laser beam irradiation and the like. With this, the branch line part concerned can be cut off from the main line part. As a result, it is possible to easily carryout repair and realize simplification of repair work and high yield of the semiconductor light emitting element chip integrated device. According to the method, for example, in the case of a light emitting diode display and the like, if there exist semiconductor light emitting element chips with leakage defection in pixels, by cutting off the branch line part to which the p-side electrode resulting leakage defection is connected, it is possible to use light emitting elements in the region of the p-side electrodes which are connected to remaining branch line parts. As a result, there is no need to exchange defective chips for repair and adopt redundancy structure, so that it is possible to control increase of costs of materials. Conventionally, the number of the p-side electrode and the n-side electrode of a semiconductor light emitting element chip is one, respectively. Therefore, if defection such as leakage defection occurs in the chip, the whole chip cannot be used. According to the method, the p-side electrode is divided into plural electrodes. With this, defective parts can be separated in the chip and normal parts can be used. Furthermore, if the semiconductor light emitting element chip is joined to the chip joining part by using a multichip transfer method using a cohesive stamp, the chip size is desired to be not smaller than tens μm square taking into consideration stability of processes because transfer yield tends to decrease as the chip size become small. It is possible to form a plurality of p-side electrodes of several μm square for the semiconductor light emitting element chip not smaller than tens μm square. Even though the chip is treated as leakage defection normally, by dividing the p-side electrode into plural electrodes, electrodes except the electrodes at defective parts can be used. Although the crucial subject of multichip transfer methods is how to repair chip defection, it is possible to decrease repair work such as exchange of chips with defection by adopting the method. With this, it is possible to easily realize, for example, a light emitting diode illumination device, a large-sized light emitting diode backlight, a large screen light emitting diode display and the like at low cost.

### BRIEF DESCRIPTION OF THE DRAWINGS

FIG. 1A A perspective view showing a vertical micro LED chip which is used in a micro LED integrated device according to a first embodiment of the invention.

FIG. 1B A cross-sectional view showing the vertical micro LED chip which is used in the micro LED integrated device according to the first embodiment of the invention.

FIG. 2A A plan view showing a mounting substrate which is used in a method of manufacturing the micro LED integrated device according to the first embodiment of the invention.

FIG. 2B A cross-sectional view showing the mounting substrate which is used in the method of manufacturing the micro LED integrated device according to the first embodiment of the invention.

FIG. 3A A cross-sectional view showing an example of a chip joining part of the upper surface of the lower electrode of the mounting substrate which is used in the method of manufacturing the micro LED integrated device according to the first embodiment of the invention.

FIG. 3B A cross-sectional view showing another example of the chip joining part of the upper surface of the lower electrode of the mounting substrate which is used in the method of manufacturing the micro LED integrated device according to the first embodiment of the invention.

FIG. 4A A plan view showing the method of manufacturing the micro LED integrated device according to the first embodiment of the invention.

FIG. 4B A cross-sectional view showing the method of manufacturing the micro LED integrated device according to the first embodiment of the invention.

FIG. 5A A plan view showing the method of manufacturing the micro LED integrated device according to the first embodiment of the invention.

FIG. 5B A cross-sectional view showing the method of manufacturing the micro LED integrated device according to the first embodiment of the invention.

FIG. 6A A plan view showing the method of manufacturing the micro LED integrated device according to the first embodiment of the invention.

FIG. 6B A cross-sectional view showing the method of manufacturing the micro LED integrated device according to the first embodiment of the invention.

FIG. 7A A plan view showing the method of manufacturing the micro LED integrated device according to the first embodiment of the invention.

FIG. 7B A cross-sectional view showing the method of manufacturing the micro LED integrated device according to the first embodiment of the invention.

FIG. 8A An enlarged plan view showing the thin film fuse shown in FIG. 7A and FIG. 7B and the area near to it.

FIG. 8B An enlarged plan view showing another thin film fuse which is different from the thin film fuse shown in FIG. 8A and the area near to it.

FIG. 9A A plan view for explaining a method of repairing the micro LED integrated device manufactured by the method of manufacturing the micro LED integrated device according to the first embodiment of the invention.

FIG. 9B A cross-sectional view for explaining the method of repairing the micro LED integrated device manufactured by the method of manufacturing the micro LED integrated device according to the first embodiment of the invention.

FIG. 10A A plan view for explaining the method of repairing the micro LED integrated device manufactured by the method of manufacturing the micro LED integrated device according to the first embodiment of the invention.

FIG. 10B A cross-sectional view for explaining the method of repairing the micro LED integrated device manufactured by the method of manufacturing the micro LED integrated device according to the first embodiment of the invention.

FIG. 11 A schematic view for explaining advantages obtained by transferring the vertical micro LED chip by a multichip transfer method using an adhesive stamp in the method of manufacturing the micro LED integrated device according to the first embodiment of the invention.

FIG. 12A A plan view showing a mounting substrate which is used in a method of manufacturing the micro LED integrated device according to a second embodiment of the invention.

FIG. 12B A cross-sectional view showing the mounting substrate which is used in the method of manufacturing the micro LED integrated device according to the second embodiment of the invention.

FIG. 13A A plan view showing the method of manufacturing the micro LED integrated device according to the second embodiment of the invention.

FIG. 13B A cross-sectional view showing the method of manufacturing the micro LED integrated device according to the second embodiment of the invention.

FIG. 14A A plan view showing the method of manufacturing the micro LED integrated device according to the second embodiment of the invention.

FIG. 14B A cross-sectional view showing the method of manufacturing the micro LED integrated device according to the second embodiment of the invention.

FIG. 15A A plan view showing a mounting substrate which is used in a method of manufacturing the micro LED integrated device according to a third embodiment of the invention.

FIG. 15B A cross-sectional view showing the mounting substrate which is used in the method of manufacturing the micro LED integrated device according to the third embodiment of the invention.

FIG. 16A A plan view showing the method of manufacturing the micro LED integrated device according to the third embodiment of the invention.

FIG. 16B A cross-sectional view showing the method of manufacturing the micro LED integrated device according to the third embodiment of the invention.

FIG. 17A A plan view showing the method of manufacturing the micro LED integrated device according to the third embodiment of the invention.

FIG. 17B A cross-sectional view showing the method of manufacturing the micro LED integrated device according to the third embodiment of the invention.

FIG. 18A A plan view showing the method of manufacturing the micro LED integrated device according to the third embodiment of the invention.

FIG. 18B A cross-sectional view showing the method of manufacturing the micro LED integrated device according to the third embodiment of the invention.

FIG. 19 A plan view showing a vertical micro LED chip which is used in a micro LED integrated device according to a fifth embodiment of the invention.

FIG. 20 A plan view showing the micro LED integrated device according to the fifth embodiment of the invention.

FIG. 21 A plan view showing a vertical micro LED chip which is used in a micro LED integrated device according to a sixth embodiment of the invention. [FIG. 22]A plan view showing the micro LED integrated device according to the sixth embodiment of the invention.

FIG. 23A A plan view showing a method of manufacturing a micro LED integrated device according to a seventh embodiment of the invention.

FIG. 23B A cross-sectional view showing the method of manufacturing the micro LED integrated device according to the seventh embodiment of the invention.

FIG. 24A A plan view showing a method of manufacturing a micro LED integrated device according to the seventh embodiment of the invention.

FIG. 24B A cross-sectional view showing the method of manufacturing the micro LED integrated device according to the seventh embodiment of the invention.

FIG. 25A A plan view showing the method of manufacturing the micro LED integrated device according to the seventh embodiment of the invention.

FIG. 25B A cross-sectional view showing the method of manufacturing the micro LED integrated device according to the seventh embodiment of the invention.

FIG. 25C A cross-sectional view showing the method of manufacturing the micro LED integrated device according to the seventh embodiment of the invention.

FIG. 26A A perspective view showing a lateral micro LED chip which is used in a micro LED integrated device according to an eighth embodiment of the invention.

FIG. 26B A cross-sectional view showing the lateral micro LED chip which is used in the micro LED integrated device according to the eighth embodiment of the invention.

FIG. 27A A plan view showing a method of manufacturing the micro LED integrated device according to the eighth embodiment of the invention.

FIG. 27B A cross-sectional view showing the method of manufacturing the micro LED integrated device according to the eighth embodiment of the invention.

FIG. 28A A plan view showing the method of manufacturing the micro LED integrated device according to the eighth embodiment of the invention.

FIG. 28B A cross-sectional view showing the method of manufacturing the micro LED integrated device according to the eighth embodiment of the invention.

FIG. 28C A cross-sectional view showing the method of manufacturing the micro LED integrated device according to the eighth embodiment of the invention.

FIG. 29 A plan view showing a mounting substrate of a passive driving system color micro LED display according to a ninth embodiment of the invention.

FIG. 30 A plan view showing the passive driving system color micro LED display according to the ninth embodiment of the invention.

FIG. 31 A plan view showing a mounting substrate of an active driving system color micro LED display according to a tenth embodiment of the invention.

FIG. 32 A plan view showing the active driving system color micro LED display according to the tenth embodiment of the invention.

FIG. 33A A plan view showing a method of manufacturing a micro LED integrated device according to an eleventh embodiment of the invention.

FIG. 33B A cross-sectional view showing the method of manufacturing the micro LED integrated device according to the eleventh embodiment of the invention.

### MODES FOR CARRYING OUT THE INVENTION

Modes for carrying out the invention (hereinafter referred as embodiments) will now be explained below.

### The First Embodiment

The micro LED integrated device according to the first embodiment is manufactured by mounting a number of vertical micro LED chips on a mounting substrate. Firstly, described is the vertical micro LED chip having a plurality of p-side electrodes and an n-side electrode on the upper surface and the lower surface, the p-side electrodes being arranged in a line or a plurality of lines.

### [Method of Manufacturing the Micro LED Integrated Device]

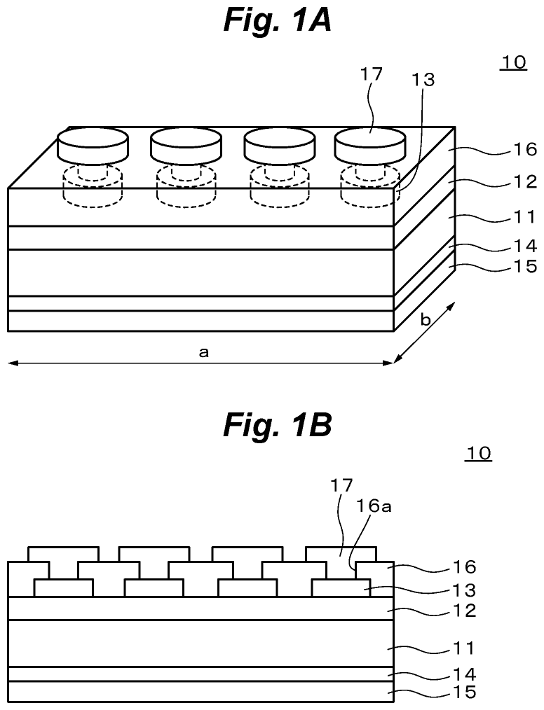

FIG. 1A and FIG. 1B show a vertical micro LED chip 10. Here, FIG. 1A is a perspective view and FIG. 1B is a cross-sectional view along lines of p-side electrodes. The vertical micro LED chip 10 uses AlGaInN-based semiconductor or AlGaInP-based semiconductor. As shown in FIG. 1A and FIG. 1B, the vertical micro LED chip 10 has a rectangular planar shape. In the vertical micro LED chip 10, an n⁺-type semiconductor layer 11, a light emitting layer 12 and p-type semiconductor layers 13 are stacked in order. The p-type semiconductor layers 13 are provided separately each other. If the thickness of the p-type semiconductor layers 13 is small and the resistivity of the p-type semiconductor layers 13 is relatively high, the spread of current through the p-type semiconductor layers 13 is not large. In this case, the p-type semiconductor layers 13 may be provided continuously. In an example shown in FIG. 1A and FIG. 1B, four circular p-type semiconductor layers 13 arranged in a line are provided as an example. However, the number of lines of the p-type semiconductor layers 13 and the number of the p-type semiconductor layers 13 in each line are not limited to this and may be selected as necessary. An n-side electrode 14 is provided on the back surface of the n⁺-type semiconductor layer 11 as a full-surface electrode and comes in ohmic contact with the n⁺-type semiconductor layer 11. Provided on the n-side electrode 14 is a Sn film 15 which is used to mount the vertical micro LED chip 10 on a mounting substrate. The thickness of the Sn film 15 is, for example, about 0.5 μm, but not limited to this. An insulating film 16 is provided so as to cover each of the p-type semiconductor layers 13. The insulating film 16 is made of, for example, a SiO₂ film. The insulating film 16 has an opening 16a at a part corresponding to each of the p-type semiconductor layers 13. The opening 16a has, for example, a circular shape. A p-side electrode 17 is provided on each of the p-type semiconductor layers 13 through the opening 16a and comes in ohmic contact with the p-type semiconductor layer 13. Four p-side electrodes 17 are provided in a line corresponding to that four p-type semiconductor layers 13 are provided in a line. The p-side electrodes 17 extend on the insulating film 16 around each opening 16a. The planar shape of the part of the insulating film 16 which extends to the insulating film 16 is, for example, a circular, but not limited to this. The p-side electrodes 17 are made of transparent electrode materials, for example, an ITO film to take out light through the p-side electrodes 17. The chip size of the vertical micro LED chip 10 is selected as necessary and is preferably selected to be not smaller than several tens of μm square. More specifically, the length a of a side in the arrangement direction of the p-side electrodes 17 is, for example, 30˜100 μm and the length b of a side in a direction at right angles to the arrangement direction of the p-side electrodes 17 is, for example, 10˜50 μm.

If the vertical micro LED chip 10 uses AlGaInN-based semiconductor and emits blue light or green light, for example, the n⁺-type semiconductor layer 11 is an n⁺-type GaN layer, the light emitting layer 12 has InₓGa₁₋ₓN/In_{y}Ga_{1-y}N multiquantum well (MQW) structure (x<y, 0≤x<1, 0≤y<1) in which the InₓGa₁₋ₓN layer as the barrier layer and the In_{y}Ga_{1-y}N layer as the well layer are alternately stacked (the In compositions x, y are determined depending on the emission wavelength of each micro LED of the vertical micro LED chip 10) and the p-type semiconductor layers 13 are p-type GaN layers. If the vertical micro LED chip 10 uses AlGaInP-based semiconductor and emits red light, for example, the n⁺-type semiconductor layer 11 is an n⁺-type AlGaInP layer, the light emitting layer 12 has InₓGa₁₋ₓP/In_{y}Ga_{1-y}P MQW structure and the p-type semiconductor layers 13 are p-type AlGaInP layers. These vertical micro LED chips 10 can be manufactured by conventionally publicly known method.

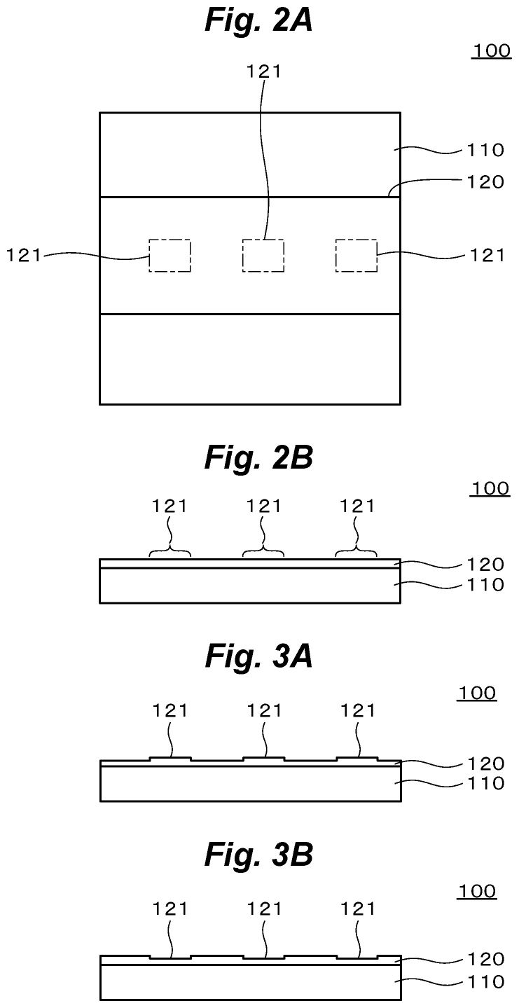

FIG. 2A and FIG. 2B show a part of a mounting substrate 400 which is used to manufacture the micro LED integrated device. Here, FIG. 2A is a plan view and FIG. 2B is a cross-sectional view along the lower electrode. As shown in FIG. 2A and FIG. 2B, a lower electrode 120 having a predetermined shape is provided on one major surface of a substrate 110. Actually, a number of lower electrodes 120 are provided, though only one of them is shown in FIG. 2A and FIG. 2B. The substrate 110 may be rigid or flexible and transparent or opaque and may be selected as necessary. The substrate 110 may be, for example, a Si substrate, a glass substrate, a glass epoxy substrate, resin film and the like. The lower electrode 120 can be formed, for example, by forming a metal film on the whole surface of the substrate 110 by a sputtering method, a vacuum evaporation method and the like and patterning the metal film to have a predetermined shape by lithography and etching. As the metal film, for example, a Ti/Al/Ti/Au layered film is used, but a Cu (or Cu alloy)/Au/Ti layered film may be also used. Thicknesses of films forming the Ti/Al/Ti/Au layered film are, for example, 5˜10 nm, 300˜1000 nm, 50 nm, 5˜100 nm in order from the bottom film. Chip joining parts 121 are provided on the lower electrode 120. The chip joining part 121 is an area to which the vertical micro LED chip 10 is joined and determined by design. The vertical micro LED chip 10 may be joined to the chip joining part 121 such that it is fully included in the chip joining part 121 or a part of the vertical micro LED chip 10 sticks out from the chip joining part 121. Actually, the chip joining parts 121 are provided in, for example, two-dimensional array, though only three of them are shown in FIG. 2A and FIG. 2B. If the upper surface of the lower electrode 120 is flat, the chip joining part 121 is an area of a part of the flat upper surface, which is shown in FIG. 2A by a dashed-and-dotted line. As shown in FIG. 3A, if a protrusion is provided in a part of the upper surface of the lower electrode 120 corresponding to the chip joining part 121, the chip joining part 121 is the upper surface of the protrusion. As shown in FIG. 3B, if a concavity is provided in a part of the upper surface of the lower electrode 120 corresponding to the chip joining part 121, the chip joining part 121 is the base of the concavity.

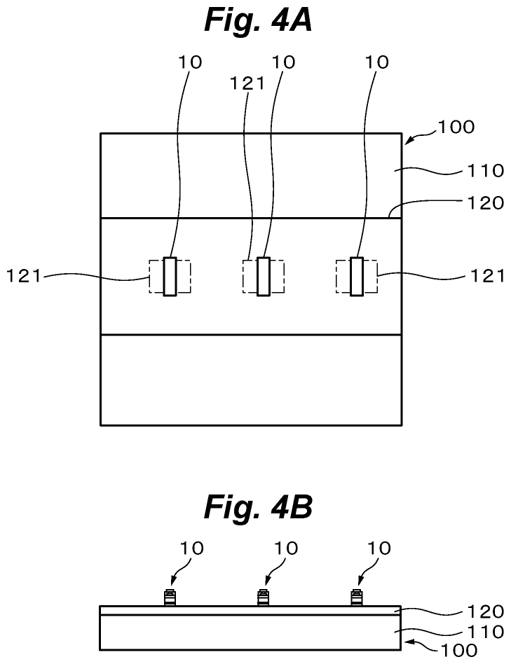

As shown in FIG. 4A and FIG. 4B, the vertical micro LED chip 10 is bonded to each of the chip joining parts 121 of the lower electrode 120 of the mounting substrate 100 by a multichip transfer method using a stamp and the like such that the Sn film 15 faces downward. Here, FIG. 4A is a plan view and FIG. 4B is a cross-sectional view. For example, if the micro LED integrated device is a color micro LED display and FIG. 4A shows a pixel formed by three vertical micro LED chips 10, the vertical micro LED chip 10 on the left side, the vertical micro LED chip 10 in the center and the vertical micro LED chip 10 on the right side form the blue (B) light emission area, the red (R) light emission area and the green (G) light emission area, respectively. If the vertical micro LED chip 10 emits blue light, RGB light emission is realized by arranging red phosphor and green phosphor over the vertical micro LED chip 10 joined to the chip joining part 121 in the R light emission area of each pixel and the vertical micro LED chip 10 joined to the chip joining part 121 in the G light emission area, respectively. And if the vertical micro LED chip 10 emits ultraviolet light, RGB light emission is realized by arranging red phosphor, green phosphor and blue phosphor over the vertical micro LED chip 10 joined to the chip joining part 121 in the R light emission area of each pixel, the vertical micro LED chip 10 joined to the chip joining part 121 in the G light emission area and the vertical micro LED chip 10 joined to the chip joining part 121 in the B light emission area, respectively.

Then, the Sn film 15 of each of the vertical micro LED chips 10 is heated by lamp, laser and the like to make melt. Thereafter, by cooling of the molten Sn, the n-side electrode 14 of the vertical micro LED chip 10 is joined electrically and mechanically to the chip joining part 121 of the lower electrode 120.

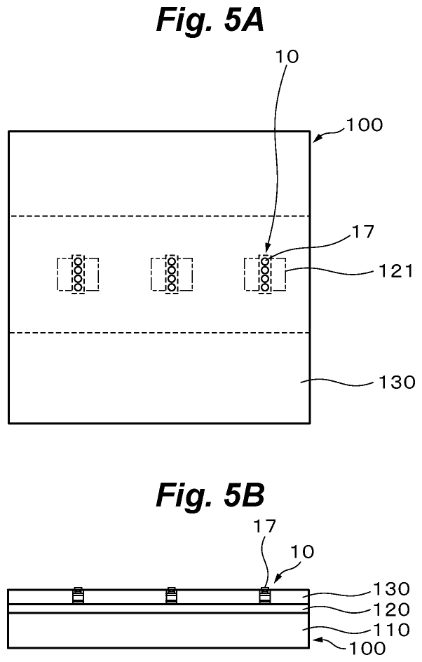

Then, as shown in FIG. 5A and FIG. 5B, after an insulating film 130 is formed on the whole surface of the mounting substrate 100 in which the vertical micro LED chip 10 is joined to the chip joining part 121 such that the surface of the insulating film 130 is almost flat, the insulating film 130 is etched by, for example, an RIE method to expose the p-side electrodes 17.

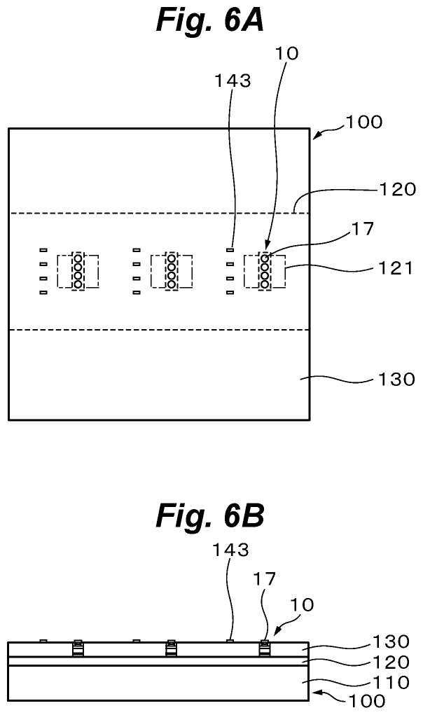

Then, as shown in FIG. 6A and FIG. 6B, formed on the insulating film 130 are thin film fuses 143 which are to be connected respectively between an upper electrode main line part 141 and a plurality of upper electrode branch line parts 142 which will be described later. The thin film fuses 143 are formed such that the number of the thin film fuses 143 (in this example 4) is equal to the number of the p-side electrodes 17 included in the vertical micro LED chip 10. The thin film fuses 143 can be formed by, for example, forming a photoresist having openings having a predetermined shape corresponding to the thin film fuse 143 on the insulating film 130 by lithography, forming a metal film thereon by a vacuum evaporation and thereafter lifting off the photoresist. The thin film fuse 143 is made of a metal thin film having a melting point not lower than 150° C. and not higher than 350° C. The metal thin film is, for example, simple metal such as In, Sn and the like or alloys such as InSn, InSnAg, AgSn, AuSn and the like.

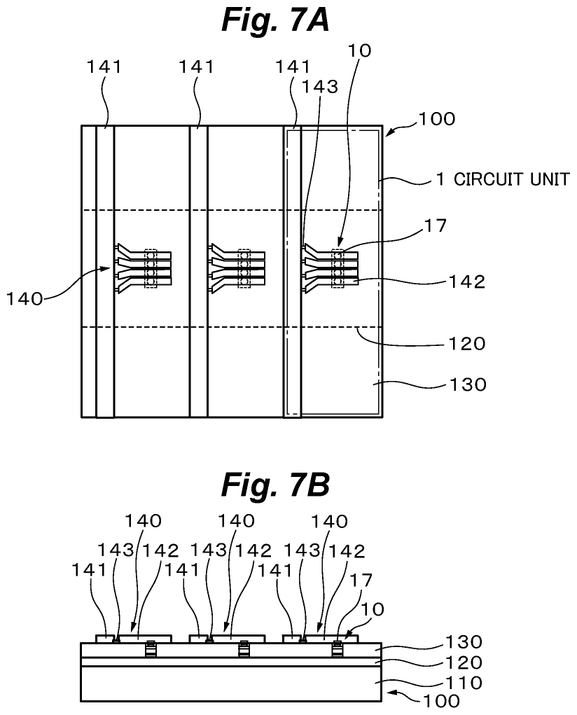

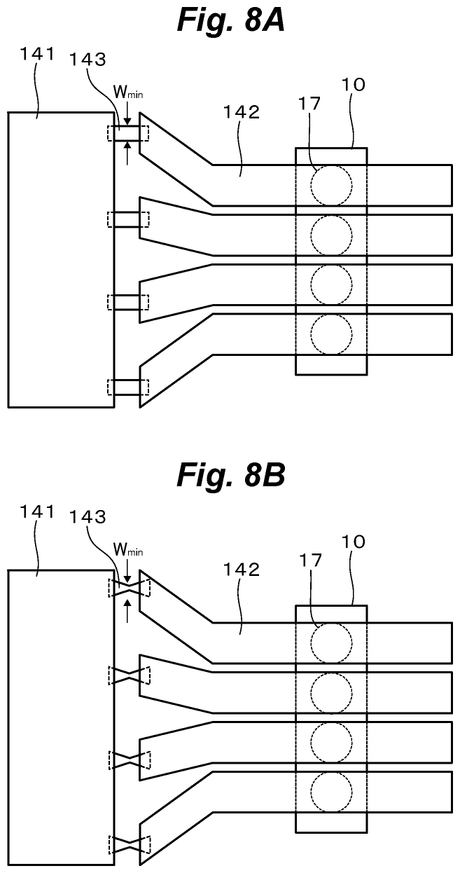

Then, as shown in FIG. 7A and FIG. 7B, formed on the insulating film 130 is a plurality of upper electrode main line parts 141 which extend in a direction at right angles to the lower electrode 120 and are parallel to each other such that the upper electrode main line part 141 overlaps one end of the thin film fuse 143. Then, formed on the insulating film 130 is a plurality of upper electrode branch line parts 142 for each chip joining part 121 which connect the p-side electrodes 17 of the vertical micro LED chip 10 and the upper electrode main line part 141 via the thin film fuse 143 (in this example, the number of the upper electrode branch line parts 142 is 4). The number of the upper electrode branch line parts 142 is equal to the number of the p-side electrodes 17 included in the vertical micro LED chip 10. Each of the upper electrode branch line parts 142 is formed such that it overlaps the other end of the thin film fuse 143 and extends parallel to the extending direction of the lower electrode 120 at the chip joining part 121 and the area near to it and comes in contact with each of the p-side electrodes 17 included in the vertical micro LED chip 10. A part of each of the upper electrode branch line parts 142 on the side of the thin film fuse 143 is folded outwardly with respect to the chip joining part 121 and the straight part near to it and the tip of the folded part overlaps with the other end of the thin film fuse 143. At least a part of each of the upper electrode branch line parts 142 which overlaps with the vertical micro LED chip 10, typically overlaps with the chip joining part 121 is made of transparent electrode materials such as ITO and the like. Other parts of each of the upper electrode branch line parts 142 may be made of other opaque electrode materials, for example, a Ti/Al/Ti/Au layered film and the like. The whole of the upper electrode branch line part 142 may be made of transparent electrode materials. The upper electrode main line part 141 and the upper electrode branch line parts 142 which are connected via the thin film fuse 143 form an upper electrode 140. In FIG. 7A, an area covered by a circuit unit which on/off can be controlled electrically is shown by a dashed-and-dotted line. The light emitting area under the p-side electrodes 17 formed in the vertical micro LED chip 10 is typically selected to be not larger than a thousandth of the area covered by one circuit unit. FIG. 8A shows an enlarged view of the thin film fuse 143 and the upper electrode main line part 141 and the upper electrode branch line parts 142 near to the thin film fuse 143. Although the thin film fuse 143 shown in FIG. 8A has a rectangular shape, the thin film fuse 143 may have a planar shape having a constricted middle part as shown in FIG. 8B. As shown in FIG. 8A and FIG. 8B, if the width of the narrowest part of the thin film fuse 143 is denoted as Wₘᵢₙ and its thickness is denoted as Train Wₘᵢₙ and Tₘᵢₙ are selected such that Wₘᵢₙ×Tₘᵢₙ<0.5 μm² is satisfied.

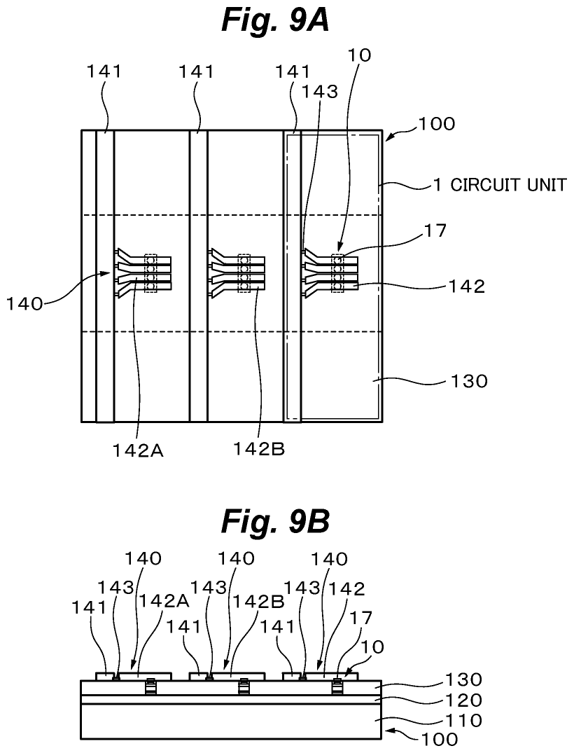

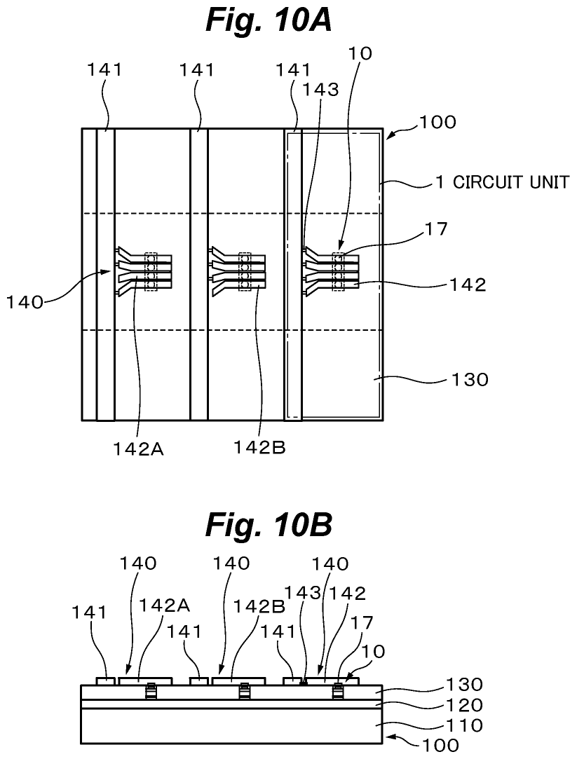

Thereafter, a voltage not higher than the threshold voltage of the vertical micro LED chip 10 (for example, about 3 V) is applied as a voltage for repair between the upper electrode branch line parts 142 and the upper electrode main line part 141 of the micro LED integrated device manufactured as described above. As a result, for example, if the p-side electrode 17 of the vertical micro LED chips 10 with leakage defection is connected to the upper electrode branch line parts 142A, 142B in FIG. 9A and FIG. 9B, a large current flows between the upper electrode branch line parts 142A, 142B and the upper electrode main line part 141 connected to the upper electrode branch line parts 142A, 142B via the thin film fuse 143 and the thin film fuse 143 melts and is cut. FIG. 10A and FIG. 10B show the state where the thin film fuse 143 between the upper electrode main line part 141 and the upper electrode branch line parts 142A, 142B is cut. In this way, repair of the micro LED integrated device can be carried out.

### [Structure of the Micro LED Integrated Device]

As shown in FIG. 7A and FIG. 7B, the micro LED integrated device has the mounting substrate 100 having the lower electrode 120 on one major surface, the chip joining part 121 provided on the lower electrode 120, the vertical micro LED chip 10 having the p-side electrodes 17 and the n-side electrode 14 on the upper surface and the lower surface joined to the chip joining parts 121 and the upper electrode 140 as the upper layer of the vertical micro LED chip 10 having the upper electrode main line part 141 and the upper electrode branch line parts 142 which are connected to the upper electrode main line part 141 via the thin film fuse 143. And, the vertical micro LED chip 10 is joined to the chip joining part 121 such that the n-side electrode 14 faces the chip joining part 121. The n-side electrode 14 and the lower electrode 120 are electrically connected each other. Each of the p-side electrode 17 of the vertical micro LED chip 10 and the upper electrode branch line parts 142 of the upper electrode 140 are electrically connected each other. Light from the vertical micro LED chip 10 is transmitted through the p-side electrodes 17 and the upper electrode branch line parts 142 and taken out to the side opposite to the substrate 110.

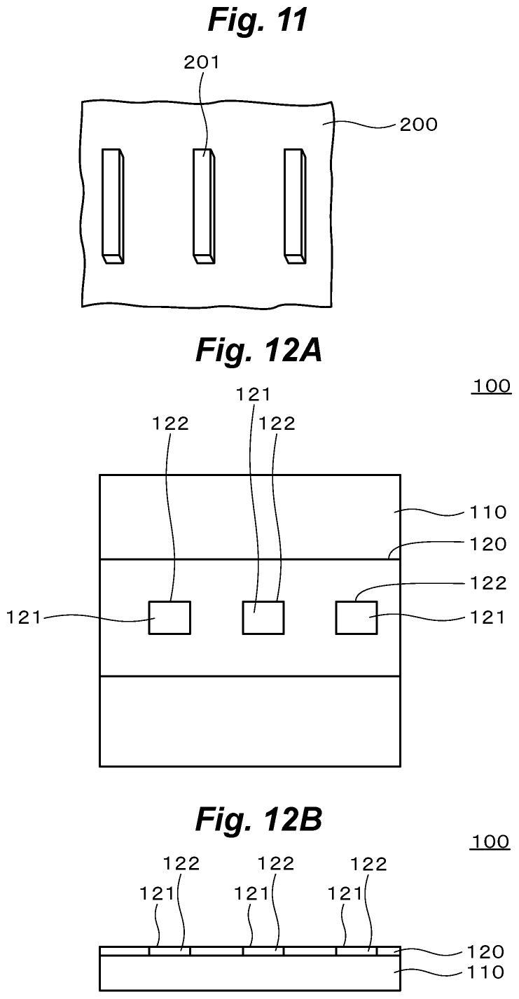

As described above, according to the first embodiment, the vertical micro LED chip 10 having the p-side electrodes 17 and the n-side electrode 14 on the upper surface and the lower surface is used, the chip joining part 421 are formed, for example in a two-dimensional array, on the lower electrode 120 of the mounting substrate 100, the vertical micro LED chip 10 is joined to the chip joining part 121 of the lower electrode 120 of the mounting substrate 100 by a multichip transfer method using a stamp and the like that the n-side electrode 14 faces downward and then the Sn film 15 is made melt and solidified to connect the n-side electrode 14 of the vertical micro LED chip 10 and the chip joining part 121 of the lower electrode 120 electrically and mechanically, whereby a micro LED integrated device such as, for example, a micro LED display, a micro LED backlight, a micro LED illumination device and the like can be easily realized at low cost, regardless of integration of degree of the vertical micro LED chip 10. Furthermore, even if there occurs defection of the p-side electrodes 17 included in the vertical micro LED chip 10, it is possible to easily repair by cutting the thin film fuse 143 between the upper electrode branch line parts 142 to which the p-side electrode 17 with defection is connected and the upper electrode main line part 141. Besides, it is possible to obtain the following advantages. That is, when the multichip transfer by a stamp is carried out, it is required an adhesive stamp for transfer to temporarily hold the chip to be transferred. The shape of the protrusion of the stamp is formed as the same as the chip. The chip size of the vertical micro LED chip 10 can be increased to, for example, (30˜100) μm×(10˜50) μm as described above. Therefore, as shown in FIG. 11, it is possible to increase the size of a protrusion 201 of a stamp 200 and to increase the contact area with the vertical micro LED chip 10. As a result, it is possible to prevent contact defection or collapse of the shape of the protrusion 201 from occurring and therefore maintain high yield transfer stably.

### The Second Embodiment

In the first embodiment, described is the micro LED integrated device which takes out light from the upper electrode 140. In the second embodiment, described is the micro LED integrated device which takes out light from the mounting substrate 100.

### [Method of Manufacturing the Micro LED Integrated Device]

FIGS. 12A and 12B show the mounting substrate 100 used to manufacture the micro LED integrated device. Here, FIG. 12A is a plan view and FIG. 12B is a cross-sectional view along the lower electrode. As shown in FIG. 12A and FIG. 12B, in the second embodiment, the mounting substrate 100 differs from the mounting substrate 100 in the first embodiment. That is, the mounting substrate 100 differs from the mounting substrate 100 in the first embodiment in that apart of the lower electrode 120 corresponding to the chip joining part 121 is made of the transparent electrode 122 and the surface of the transparent electrode 122 forms the chip joining part 121 and the substrate 110 is transparent for light from the vertical micro LED chip 10. Others of the mounting substrate 100 are the same as the first embodiment.

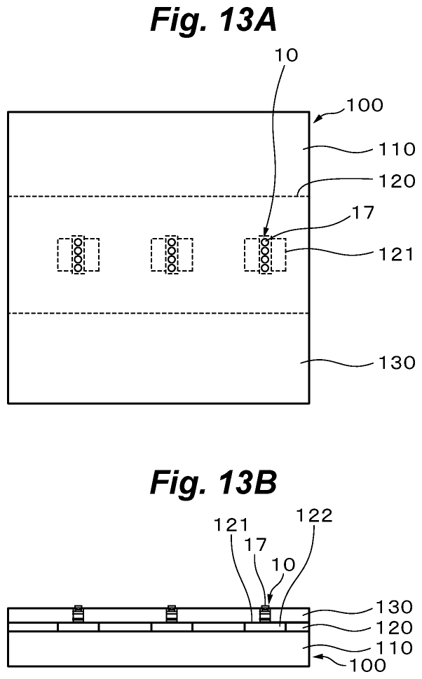

As shown in FIG. 13A and FIG. 13B, the vertical micro LED chip 10 is bonded to each of the chip joining parts 121 of the lower electrode 120 of the mounting substrate 100 by a multi-chip transfer method using a stamp and the like such that the Sn film 15 faces downward. Here, FIG. 13A is a plan view and FIG. 13B is a cross-sectional view. Although not illustrated particularly, because light is taken out from the side of the Sn film 15, the n-side electrode 14 and the Sn film 15 do not cover the whole surface of the lower part of the n⁺-type semiconductor layer 11 of the vertical micro LED chip 10 but formed only on a part of the surface of the lower part of the n⁺-type semiconductor layer 11.

Then, the Sn film 15 of each of the vertical micro LED chips 10 is heated by lamp, laser and the like to make melt. Thereafter, by cooling of the molten Sn, then-side electrode 14 of the vertical micro LED chip 10 is joined electrically and mechanically to the chip joining part 121 of the lower electrode 120.

Then, after the insulating film 130 is formed on the whole surface of the mounting substrate 100 in which the vertical micro LED chip 140 is joined to the chip joining part 121 such that the surface of the insulating film 130 is almost flat, the insulating film 130 is etched by, for example, the RIE method to expose the p-side electrodes 17.

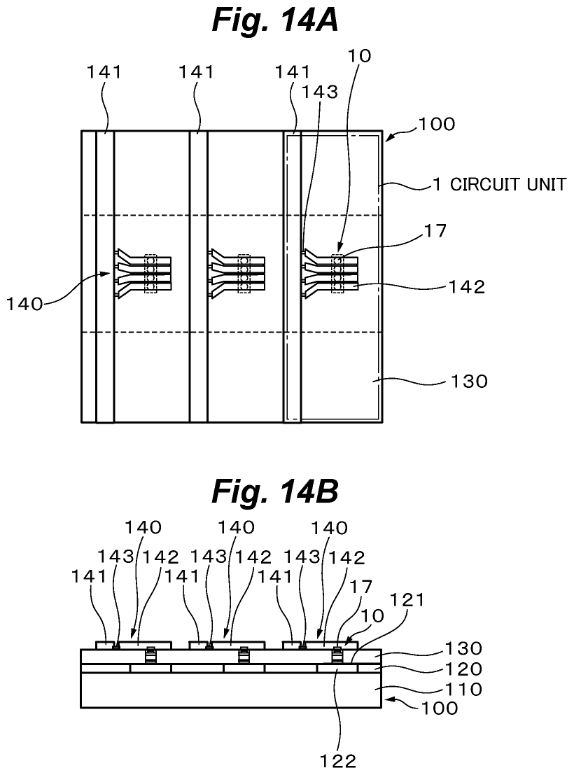

Then, as shown in FIG. 14A and FIG. 14B, formed on the insulating film 130 are the thin film fuses 143, the upper electrode main line part 141 and the upper electrode branch line parts 142 as the same as the first embodiment. The upper electrode main line part 141 and the upper electrode branch line parts 142 form the upper electrode 140.

Thereafter, repair of the micro LED integrated device is carried out as necessary.

### [Structure of the Micro LED Integrated Device]

As shown in FIG. 14A and FIG. 14B, the micro LED integrated device has the mounting substrate 100 having the lower electrode 120 on one major surface of the substrate 110 which is transparent for light from the vertical micro LED chip 10, the chip joining part 121 provided on the transparent electrode 122 provided partly on the lower electrode 120, the vertical micro LED chip 10 joined to the chip joining part 121 and the upper electrode 140 as the upper layer of the vertical micro LED chip 10 having the upper electrode main line part 141 and the upper electrode branch line parts 142 which are connected to the upper electrode main line part 141 via the thin film fuse 143. And, the vertical micro LED chip 10 is joined to the chip joining part 121 such that the n-side electrode 14 faces the chip joining part 121. The n-side electrode 14 and the lower electrode 120 are electrically connected each other. Each of the p-side electrodes 17 of the vertical micro LED chip 10 and the upper electrode branch line parts 142 of the upper electrode 140 are electrically connected each other. Light from the vertical micro LED chip 10 is transmitted through the transparent electrode 122 of the chip joining part 121 of the lower electrode 120 and the substrate 110 and taken out to the outside.

According to the second embodiment, a part of the lower electrode 120 corresponding to the chip joining part 121 is made of the transparent electrode 122 and the substrate 110 is transparent for light from the vertical micro LED chip 10. Therefore, light from the vertical micro LED chip 10 can be transmitted through the transparent electrode 122 of the chip joining part 121 of the lower electrode 120 and the substrate 110 and taken out to the outside. In addition, the same advantages as the first embodiment can be obtained.

### The Third Embodiment

In the first embodiment, described is the micro LED integrated device in which the thin film fuse 143 is connected between the upper electrode main line part 141 of the upper electrode 140 and the upper electrode branch line parts 142. In the third embodiment, described is the micro LED integrated device in which the thin film fuse is connected between a lower electrode main line part and a plurality of lower electrode branch line parts of the lower electrode 120.

### [Method of Manufacturing the Micro LED Integrated Device]

The vertical micro LED chip 10 used to manufacture the micro LED integrated device is almost the same as the vertical micro LED chip 10 in the first embodiment. The vertical micro LED chip 10 differs from the vertical micro LED chip 10 in the first embodiment in that the p-side electrodes 17 are made of materials such as Ag and the like having high reflectivity for light from the vertical micro LED chip 10, the n-side electrode 14 does not cover the whole surface of the lower part of the n⁺-type semiconductor layer 11 but the n-side electrode 14 is formed on only a part of the lower part and the Sn film 15 is formed on the p-side electrode 17 not on the n-side electrode 14.

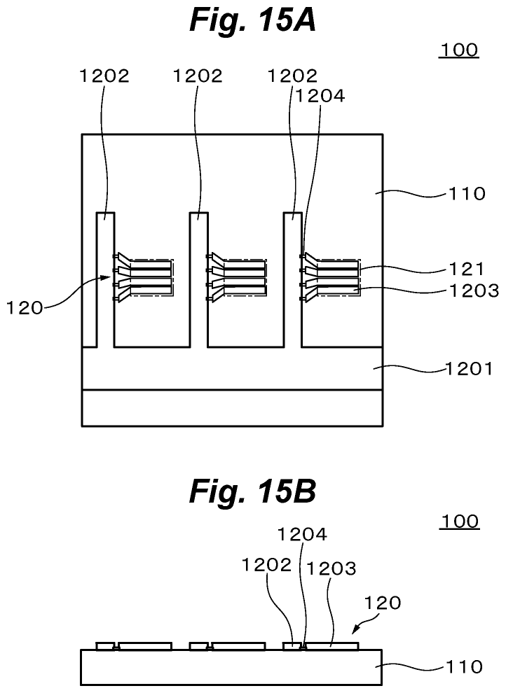

FIG. 15A and FIG. 15B show the mounting substrate 100 used to manufacture the micro LED integrated device. Here, FIG. 15A is a plan view and FIG. 15B is a cross-sectional view along the lower electrode branch line parts and the lower electrode main line part near to them. As shown in FIG. 15A and FIG. 15B, the lower electrode 120 is provided on one major surface of the substrate 110. In this case, the lower electrode 120 comprises a wide lower electrode main line part 1201 which extends in a direction, a plurality of lower electrode main line parts 1202 which are narrower than the lower electrode main line part 1201 and branch from the lower electrode main line part 1201 in a direction at right angles to the lower electrode main line part 1201, and a plurality of lower electrode branch line parts 1203 which are provided near to the lower electrode main line parts 1202 and comprises a straight part extending in a direction at right angles to the lower electrode main line parts 1202, that is, in a direction parallel to the lower electrode main line part 1201 and a part folded outward for the straight part. A thin film fuse 1204 is connected between the lower electrode main line part 1202 and the lower electrode branch line parts 1203 near to the lower electrode main line part 1202. The chip joining part 121 is formed by an area including a part of the upper surface of each of the lower electrode branch line parts 1203. The lower electrode branch line parts 1203 are formed by, for example, a Ti/Al/Ti/Au/Ti layered film and the like. Details of the substrate 110 are the same as the first embodiment. The thin film fuse 1204 is as the same as the thin film fuse 143 in the first embodiment. The number, width, intervals and the like of the lower electrode branch line parts 1203 are as the same as the upper electrode branch line parts 142 in the first embodiment.

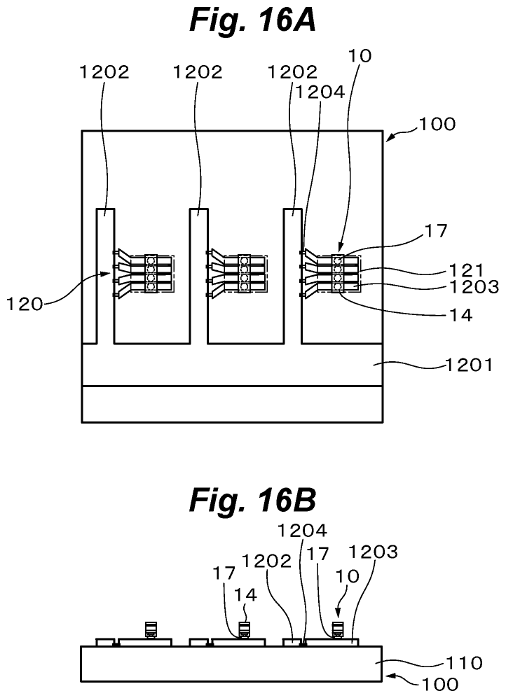

As shown in FIG. 16A and FIG. 16B, the vertical micro LED chip 10 is joined to the chip joining part 121 by a multichip transfer method using a stamp and the like such that each of the p-side electrodes 17 faces the lower electrode branch line part 1203.

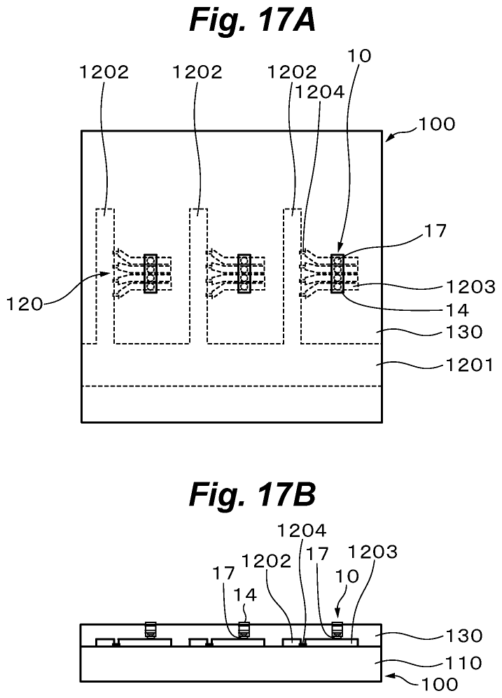

Then, as shown in FIG. 17A and FIG. 17B, after the insulating film 130 is formed on the whole surface of the mounting substrate 100 in which the vertical micro LED chip 10 is joined to the chip joining part 121 such that the surface of the insulating film 130 is almost flat, the insulating film 130 is etched by, for example, the RIE method to expose the n-side electrode 14.

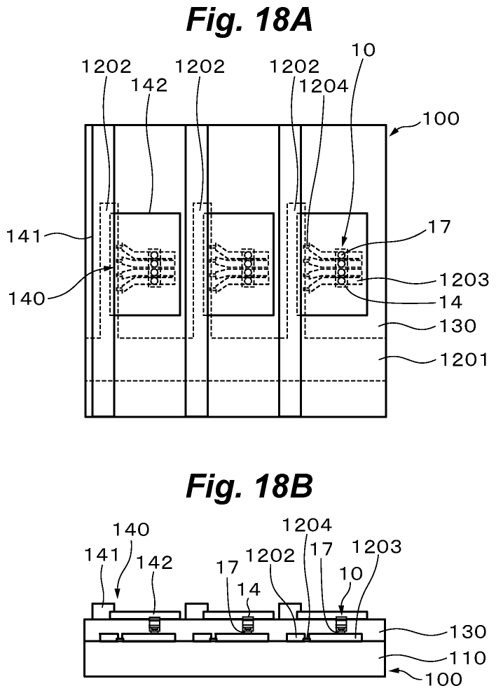

Then, as shown in FIG. 18A and FIG. 18B, formed on the insulating film 130 is a single wide upper electrode branch line part 142 such that it covers almost of the lower electrode branch line parts 1203 which are connected to one lower electrode main line part 1202 via the thin film fuse 1204. The upper electrode branch line parts 142 are made of transparent electrode materials such as ITO. Then, the upper electrode main line part 141 parallel to each of the lower electrode main line parts 1202 of the lower electrode 120 are formed corresponding to the lower electrode main line part 1202 such that the upper electrode main line part 141 overlaps the upper electrode branch line part 142 partly and is electrically connected thereto.

Thereafter, repair of the micro LED integrated device is carried out as necessary as the same as the first embodiment.

### [Structure of the Micro LED Integrated Device]

As shown in FIG. 18A and FIG. 18B, the micro LED integrated device has the mounting substrate 100 having the lower electrode 120 including the lower electrode main line part 1202 and the lower electrode branch line parts 1203 which are connected each other by the thin film fuse 1204 on one major surface, the chip joining part 121 formed by the area including a part of the upper surface of each of the lower electrode branch line parts 1203, the vertical micro LED chip 10 joined to the chip joining part 121 and the upper electrode 140 as the upper layer of the vertical micro LED chip 10 having the upper electrode main line part 141 and the upper electrode branch line parts 142 which are connected thereto. And, the vertical micro LED chip 10 is joined to the chip joining part 121 such that the p-side electrodes 17 face the chip joining part 121. Each of the p-side electrodes 17 and each of the lower electrode branch line parts 1203 are electrically connected each other. The n-side electrode 14 of the vertical micro LED chip 10 and the upper electrode branch line parts 142 of the upper electrode 140 are electrically connected each other. Light from the vertical micro LED chip 10 is transmitted through the upper electrode branch line parts 142 and taken out to the side opposite to the substrate 110. In this case, since the p-side electrodes 17 of the vertical micro LED chip 10 is made by materials having high reflectivity such as Ag, light from the vertical micro LED chip 10 is reflected upward by the p-side electrodes 17, resulting increase of the quantity of light taken out.

According to the third embodiment, it is possible to obtain the same advantages as the first embodiment.

### The Fourth Embodiment

In the third embodiment, described is the micro LED integrated device in which light is taken out from the side of the upper electrode 140. In the fourth embodiment, described is the micro LED integrated device in which light is taken out from the mounting substrate 100.

### [Method of Manufacturing the Micro LED Integrated Device]

The vertical micro LED chip 10 used to manufacture the micro LED integrated device is almost the same as the vertical micro LED chip 10 in the first embodiment. The vertical micro LED chip 10 differs from the vertical micro LED chip 10 in the first embodiment in that the Sn film 15 is formed on the p-side electrodes 17 not on the n-side electrode 14.

The mounting substrate 100 used to manufacture the micro LED integrated device is almost the same as the mounting substrate 100 in the third embodiment. The mounting substrate 100 differs from the mounting substrate 100 in the third embodiment in that the straight part of the lower electrode branch line parts 1203 which crosses the chip joining part 121 is made of transparent electrode materials such as ITO and the substrate 110 is transparent for light from the vertical micro LED chip 10.

As the same as the third embodiment, the vertical micro LED chip 10 is joined to the chip joining part 121 of the lower electrode 120 of the mounting substrate 100, the insulating film 130 is formed, the n-side electrode 14 of the vertical micro LED chip 10 is exposed and the upper electrode 140 having the upper electrode main line part 141 and the upper electrode branch line part 142 connected thereto. In this case, the upper electrode branch line parts 142 are formed by, for example, a Ti/Al/Ti/Au/Ti layered film and the like.

Thereafter, repair of the micro LED integrated device is carried out as necessary as the same as the first embodiment.

### [Structure of the Micro LED Integrated Device]

The micro LED integrated device has the mounting substrate 100 having the lower electrode 120 including the lower electrode main line part 1202 and the lower electrode branch line parts 1203 which are connected each other by the thin film fuse 1204 on one major surface of the substrate 110 which is transparent for light from the vertical micro LED chip 10, the chip joining part 121 formed by the area including a part of the upper surface of each of the lower electrode branch line parts 1203, the vertical micro LED chip 10 joined to the chip joining part 121 and the upper electrode 140 as the upper layer of the vertical micro LED chip 10 having the upper electrode main line part 141 and the upper electrode branch line parts 142 connected thereto. And, the vertical micro LED chip 10 is joined to the chip joining part 121 such that the p-side electrodes 17 face the chip joining part 121. Each of the p-side electrodes 17 and each of the lower electrode branch line parts 1203 are electrically connected each other. The n-side electrode 14 of the vertical micro LED chip 10 and the upper electrode branch line parts 142 of the upper electrode 140 are electrically connected each other. Light from the vertical micro LED chip 10 is transmitted through the lower electrode branch line parts 1203 and the substrate 110 and taken out to the outside.

According to the fourth embodiment, since the lower electrode branch line parts 1203 and the substrate 110 are transparent for light from the vertical micro LED chip 10, light from the vertical micro LED chip 10 can be transmitted through the lower electrode branch line parts 1203 and the substrate 110 and taken out to the outside. In addition, the same advantages as the first embodiment can be obtained.

### The Fifth Embodiment

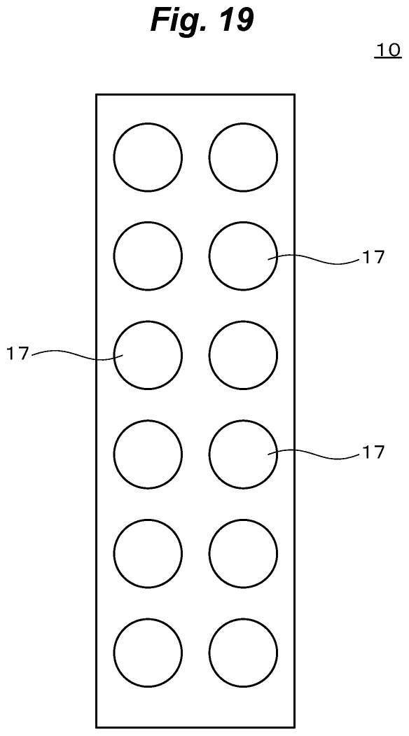

In the first embodiment, used is the vertical micro LED chip 10 having the p-side electrodes 17 and the n-side electrode 14 on the upper surface and the lower surface, the p-side electrodes 17 being arranged in a line. The fifth embodiment differs from the first embodiment in that the vertical micro LED chip 10 having the p-side electrodes 17 and the n-side electrode 14 on the upper surface and the lower surface, the p-side electrodes 17 being arranged in two lines. FIG. 19 shows the vertical micro LED chip 10.

### [Method of Manufacturing the Micro LED Integrated Device]

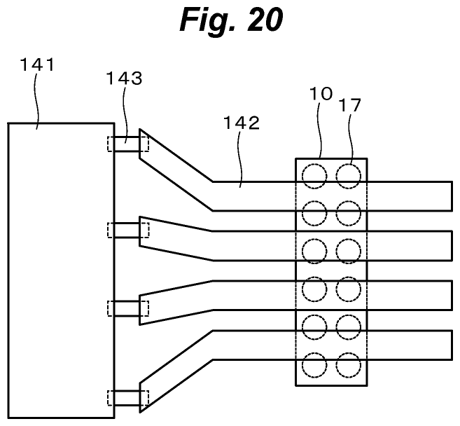

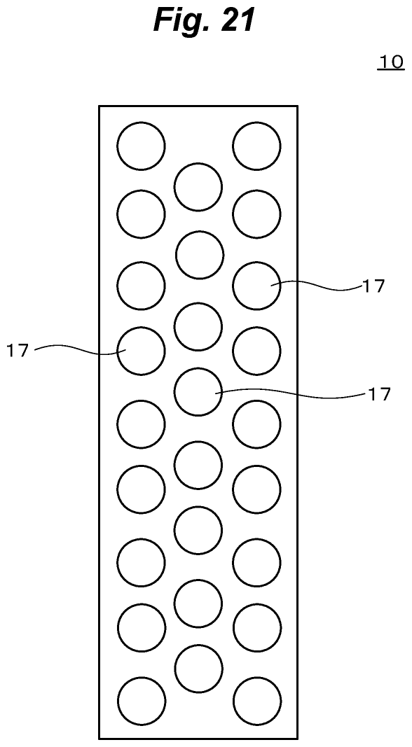

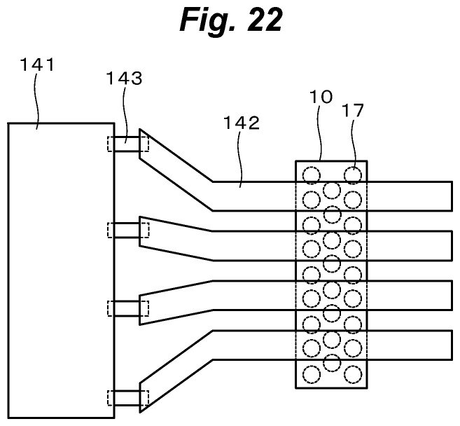

The method of manufacturing the micro LED integrated device is the same as the method of manufacturing the micro LED integrated device according to the first embodiment except that the vertical micro LED chip 10 having the p-side electrodes 17 and the n-side electrode 14 on the upper surface and the lower surface, the p-side electrodes 17 being arranged in two lines is joined to the chip joining part 121 in the step shown in FIG. 4A and FIG. 4B and each of the upper electrode branch line parts 142 comes in contact with two p-side electrodes 17 in the short side direction of the vertical micro LED chip 10 in the step shown in FIG. 7A and FIG. 7B. FIG. 20 shows the area near to the upper electrode branch line parts 142 of the micro LED integrated device in which each of the upper electrode branch line parts 142 comes in contact with two p-side electrodes 17 in the short side direction of the vertical micro LED chip 10.

### [Micro LED Integrated Device]

As shown in FIG. 20, the micro LED integrated device has the same structure as the micro LED integrated device according to the first embodiment except that the vertical micro LED chip 10 having the p-side electrodes 17 and the n-side electrode 14 on the upper surface and the lower surface, the p-side electrodes 17 being arranged in two lines is joined to the chip joining part 121 and each of the upper electrode branch line parts 142 comes in contact with two p-side electrodes 17 in the short side direction of the vertical micro LED chip 10.

According to the fifth embodiment, the same advantages as the first embodiment can be obtained.

### The Sixth Embodiment

In the first embodiment, used is the vertical micro LED chip 10 having the p-side electrodes 17 and the n-side electrode 14 on the upper surface and the lower surface, the p-side electrodes 17 being arranged in a line. The sixth embodiment differs from the first embodiment in that the vertical micro LED chip 10 having the p-side electrodes 17 and the n-side electrode 14 on the upper surface and the lower surface, the p-side electrodes 17 being arranged in three lines. FIG. 21 shows the vertical micro LED chip 10.

### [Method of Manufacturing the Micro LED Integrated Device]

The method of manufacturing the micro LED integrated device is the same as the method of manufacturing the micro LED integrated device according to the first embodiment except that the vertical micro LED chip 10 having the p-side electrodes 17 and the n-side electrode 14 on the upper surface and the lower surface, the p-side electrodes 17 being arranged in three lines is joined to the chip joining part 121 in the step shown in FIG. 4A and FIG. 4B and each of the upper electrode branch line parts 142 comes in contact with at least two p-side electrodes 17 in the short side direction of the vertical micro LED chip 10 in the step shown in FIG. 7A and FIG. 7B. FIG. 22 shows the area near to the upper electrode branch line parts 142 of the micro LED integrated device in which each of the upper electrode branch line parts 142 comes in contact with at least two p-side electrodes 17 in the short side direction of the vertical micro LED chip 10.

### [Micro LED Integrated Device]

As shown in FIG. 22, the micro LED integrated device has the same structure as the micro LED integrated device according to the first embodiment except that the vertical micro LED chip 10 having the p-side electrodes 17 and the n-side electrode 14 on the upper surface and the lower surface, the p-side electrodes 17 being arranged in three lines is joined to the chip joining part 121 and each of the upper electrode branch line parts 142 comes in contact with at least two p-side electrodes 17 in the short side direction of the vertical micro LED chip 10.

According to the sixth embodiment, the same advantages as the first embodiment can be obtained.

### The Seventh Embodiment

### [Method of Manufacturing the Micro LED Integrated Device]

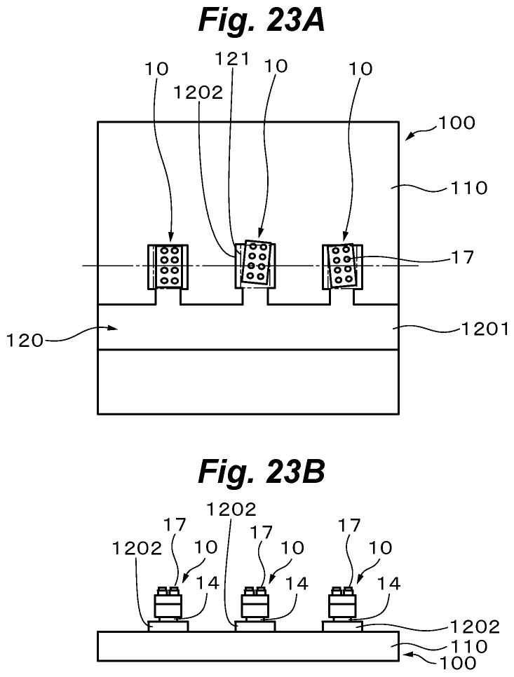

In the seventh embodiment, as shown in FIG. 23A and FIG. 23B, used is the mounting substrate 100 in which the lower electrode 120 comprising the lower electrode main line part 1201 and the lower electrode main line parts 1202 which branch from the lower electrode main line part 1201 in a direction at right angles to the lower electrode main line part 1201 is provided on one major surface of the substrate 110. Here, FIG. 23A is a plan view and FIG. 23B is a cross-sectional view along a dashed-and-dotted line in FIG. 23A. The end of the lower electrode main line part 1202 is formed to be wide and the chip joining part 121 is provided on the upper surface of the end. And, the vertical micro LED chip 10 is joined to the chip joining part 121 by the method described above such that the n-side electrode 14 faces the chip joining part 121. In FIG. 23A and FIG. 23B, shown is as an example the vertical micro LED chip 10 having the p-side electrodes 17 and the n-side electrode 14 on the upper surface and the lower surface, the p-side electrodes 17 being arranged in two lines including four p-side electrodes 17, respectively. However, arrangement of the p-side electrodes 17 is not limited to this and the p-side electrodes 17 may be arranged in a line or three lines or more. As shown in FIG. 23A and FIG. 23B, there exist among the vertical micro LED chips 10 joined to the chip joining parts 121 the vertical micro LED chips 10 which are joined to the chip joining parts 121 in positions slightly rotated with respect to the chip joining part 121.

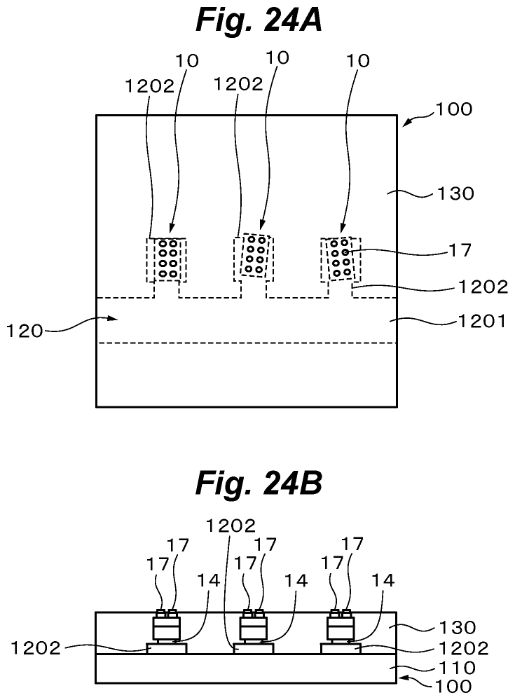

Then, as shown in FIG. 24A and FIG. 24B, after the insulating film 130 is formed on the whole surface of the mounting substrate 100 in which the vertical micro LED chip 10 is joined to the chip joining part 121 such that the surface of the insulating film 130 is almost flat, the insulating film 130 is etched by, for example, the RIE method to expose the p-side electrode 17. Here, FIG. 24A is a plan view and FIG. 24B is a cross-sectional view.

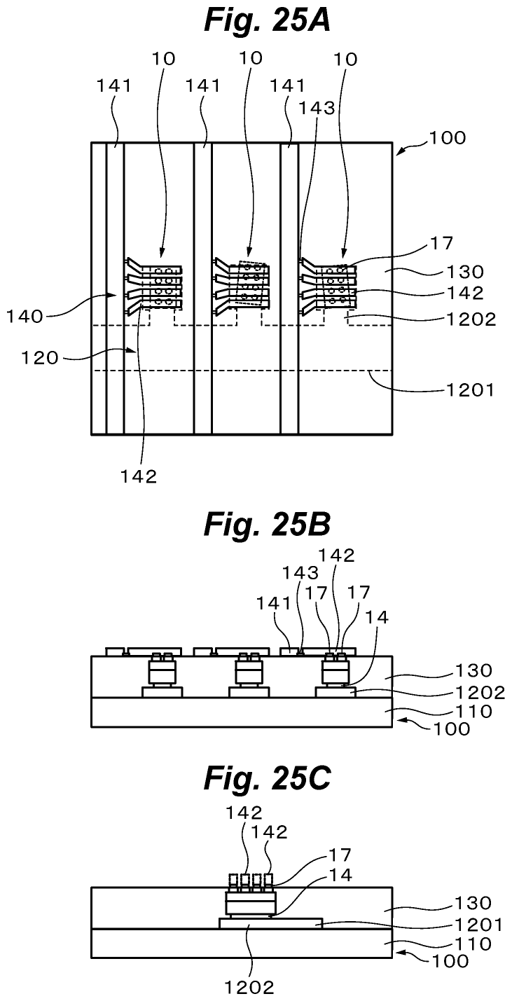

Then, as shown in FIG. 25A, FIG. 25B and FIG. 25C, formed on the insulating film 130 are the upper electrode main line part 141, the upper electrode branch line parts 142 and the thin film fuses 143 as the same as the first embodiment. Here, FIG. 25A is a plan view, FIG. 25B is a cross-sectional view similar to FIG. 23A and FIG. 25C is a cross-sectional view crossing the chip joining part 121 in a direction at right angles to the cross-section shown in FIG. 25B. The upper electrode branch line parts 142 are made of transparent electrode materials such as ITO and the like. The upper electrode 140 is formed by the upper electrode main line part 141 and the upper electrode branch line parts 142. In this case, the p-side electrodes 17 of the vertical micro LED chip 10 are arranged in two lines including four p-side electrodes 17, respectively. Therefore, among all vertical micro LED chips 10 joined to the chip joining parts 121 including the vertical micro LED chips 10 which are joined to the chip joining parts 121 in positions slightly rotated with respect to the chip joining part 121, each of the upper electrode branch line parts 142 is always connected to at least one p-side electrode 17.

Thereafter, repair of the micro LED integrated device is carried out as necessary as the same as the first embodiment.

### [Structure of the Micro LED Integrated Device]

As shown in FIG. 25A, FIG. 25B and FIG. 25C, the micro LED integrated device has the mounting substrate 100 having the lower electrode 120 comprising the lower electrode main line part 1201 and the lower electrode branch line parts 1202 which branch from the lower electrode main line part 1201 in the direction at right angles to the lower electrode main line part 1201 on one major surface, the chip joining part 121 formed by the upper surface of the wide end of the lower electrode branch line part 1202, the vertical micro LED chip 10 joined to the chip joining parts 121 and the upper electrode 140 as the upper layer of the vertical micro LED chip 10 having the upper electrode main line part 141 and the upper electrode branch line parts 142 connected each other via the thin film fuse 143. And, the vertical micro LED chip 10 is joined to the chip joining part 121 such that the n-side electrode 14 faces the chip joining part 121. The n-side electrode 14 and the lower electrode branch line part 1202 are electrically connected each other. The p-side electrode 17 and the upper electrode branch line parts 142 are electrically connected each other. Light from the vertical micro LED chip 10 is transmitted through the upper electrode branch line parts 142 and taken out to the side opposite to the substrate 110.

According to the seventh embodiment, the same advantages as the first embodiment can be obtained.

### The Eighth Embodiment

### [Method of Manufacturing the Micro LED Integrated Device]

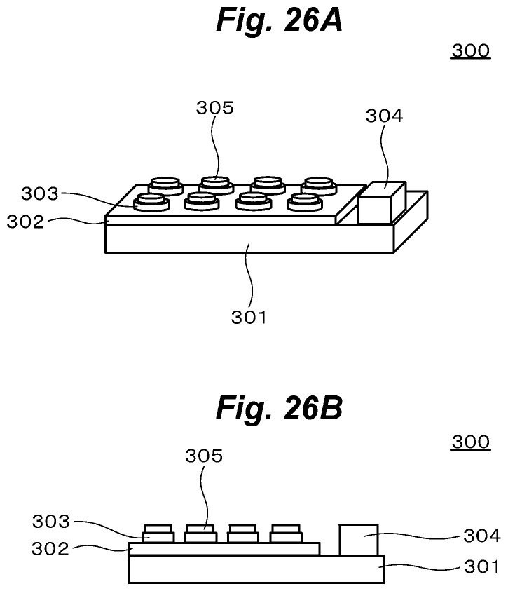

FIG. 26A and FIG. 26B show a lateral micro LED chip 300. Here, FIG. 26A is a perspective view and FIG. 26B is a cross-sectional view along a line of p-side electrodes. The lateral micro LED chip 300 uses AlGaInN-based semiconductor. As shown in FIG. 26A and FIG. 26B, the lateral micro LED chip 300 has a rectangular planar shape. In the lateral micro LED chip 300, an n⁺-type semiconductor layer 301, a light emitting layer 302 and p-type semiconductor layers 303 are stacked in order. The light emitting layer 302 is provided on the n⁺-type semiconductor layer 301 partly and the n⁺-type semiconductor layer 301 which is not covered by the light emitting layer 302 is exposed. The p-type semiconductor layers 303 are provided separately each other. In an example shown in FIG. 26A and FIG. 26B, eight circular p-type semiconductor layers 303 are provided in two lines including four p-type semiconductor layers 13, respectively as an example. However, the number of lines of the p-type semiconductor layers 303 and the number of the p-type semiconductor layers 303 in each line are not limited to this and may be selected as necessary. An n-side electrode 304 is provided on the n⁺-type semiconductor layer 301 and comes in ohmic contact with the n⁺-type semiconductor layer 301. A p-side electrode 305 is provided on each of the p-type semiconductor layers 303 and comes in ohmic contact with the p-type semiconductor layer 303. Two lines of p-side electrodes 305, each line including four p-side electrodes 305 are provided corresponding to that two lines of p-type semiconductor layers 303, each line including four p-type semiconductor layers 303 are provided. The height of the n-side electrode 304 and the p-side electrodes 305 are the same. Although not illustrated, provided on the n-side electrode 304 and the p-side electrodes 305, respectively is a Sn film which is used to mount the lateral micro LED chip 300 on a mounting substrate. If the lateral micro LED chip 300 uses AlGaInN-based semiconductor and emits blue light or green light, details of the n⁺-type semiconductor layer 301, the light emitting layer 302 and the p-type semiconductor layers 303 are the same as the vertical micro LED chip 10 described in the first embodiment.

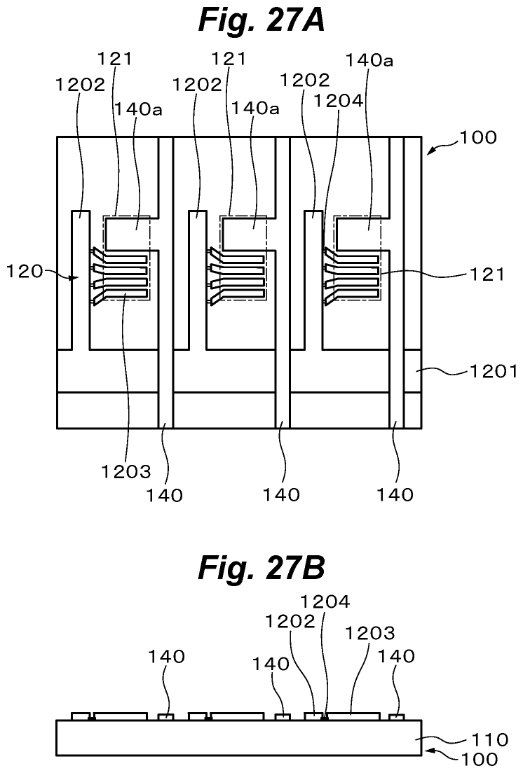

In the eighth embodiment, used is the mounting substrate 100 shown in FIG. 27A and FIG. 27B as the same as the third embodiment. Here, FIG. 27A is a plan view and FIG. 27B is a cross-sectional view along the lower electrode. As shown in FIG. 27A and FIG. 27B, provided on one major surface of the substrate 110 is the lower electrode 120 formed by the lower electrode main line part 1201, the lower electrode main line parts 1202 and the lower electrode branch line parts 1203. The thin film fuse 1204 is connected between the lower electrode main line parts 1202 and the lower electrode branch line parts 1203.

An insulating film (not illustrated) is formed on the mounting substrate 100. Thereafter, formed on the insulating film are the upper electrodes 140 parallel to the upper electrode main line parts 1202 such that they pass through positions apart from the lower electrode branch line parts 1203 which are connected to the lower electrode main line part 1202 via the thin film fuse 1204. The thickness of the upper electrode 140 is selected to be as the same as the thickness of the lower electrode branch line parts 1203. The insulating film is formed only at the intersection of the lower electrode main line part 1201 and the upper electrode 140. And the lower electrode main line part 1201 and the upper electrode 140 are insulated each other by the insulating film. Provided in the upper electrode 140 is a rectangular branch line part 140a protruding in a direction at right angles to the upper electrode 140 such that it extends over a position near to the lower electrode branch line parts 1203 which are connected to the lower electrode main line part 1202 via the thin film fuse 1204. In this case, the chip joining part 121 is formed by a rectangular area including at least a part of the upper surface of each of the lower electrode branch line parts 1203 and a part of the upper surface of the branch line part 140a of the upper electrode 140.

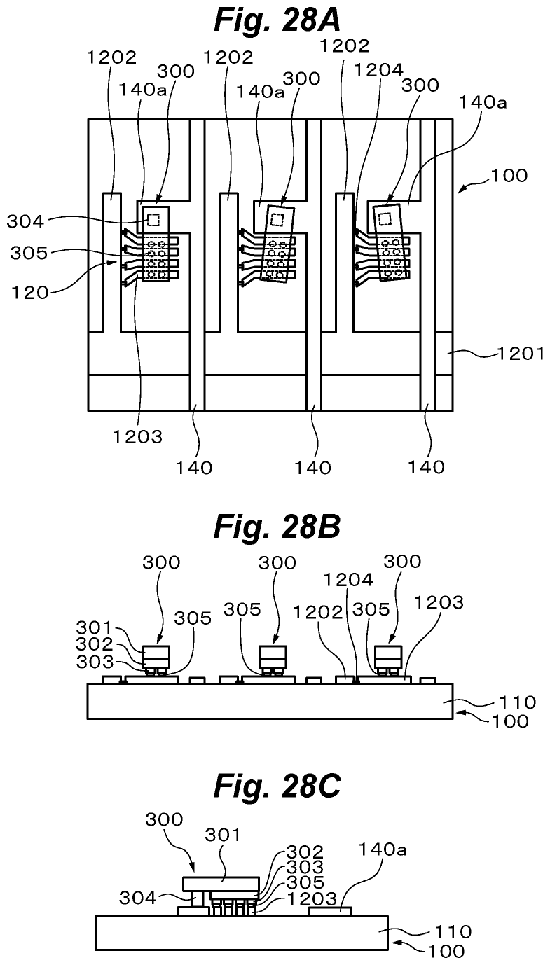

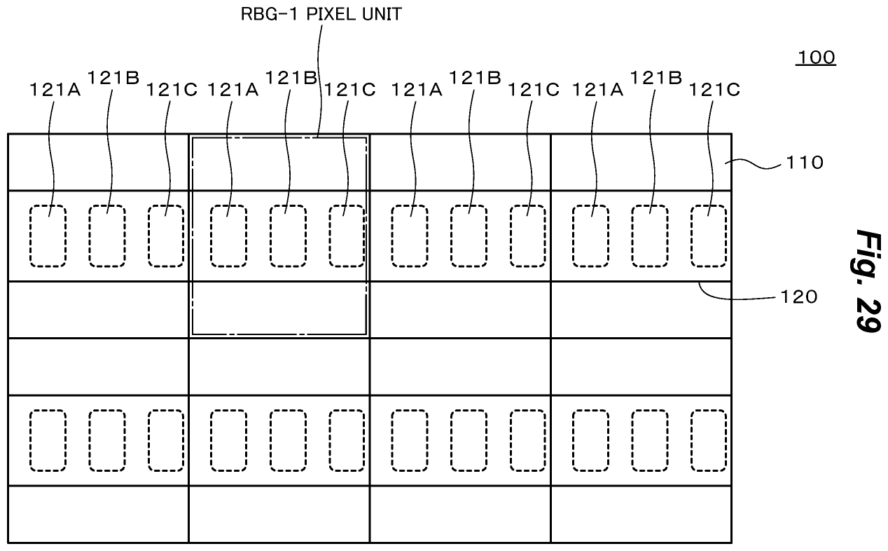

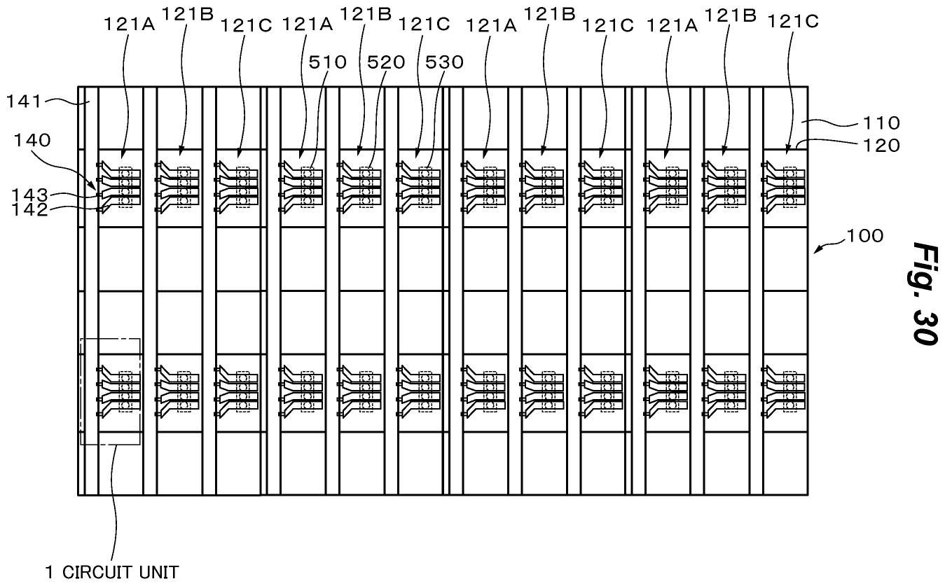

Then, as shown in FIG. 28A, FIG. 28B and FIG. 28C, the lateral micro LED chip 300 is joined to the chip joining part 121 by the method described above such that the n-side electrode 304 and the p-side electrodes 305 face the chip joining part 121. In this case, the n-side electrode 304 is located on the branch line part 140a of the upper electrode 140 and the p-side electrodes 305 are located on the lower electrode branch line parts 1203. Here, FIG. 28A is a plan view, FIG. 28B is a cross-sectional view along the lower electrode and FIG. 28C is a cross-sectional view crossing the chip joining part.

Thereafter, repair of the micro LED integrated device is carried out as necessary as the same as the first embodiment.

### [Structure of the Micro LED Integrated Device]

As shown in FIG. 28A, FIG. 28B and FIG. 28C, the micro LED integrated device has the mounting substrate 100 having the lower electrode 120 including the lower electrode main line parts 1202 and the lower electrode branch line parts 1203 which are connected by the thin film fuse 1204 and the upper electrode 140 as the upper layer of the lower electrode 120 on one major surface, the chip joining part 121 formed by the area including a part of the upper surface of each of the lower electrode branch line parts 1203 of the lower electrode 120 and a part of the upper surface of the branch line part 140a of the upper electrode 140 and the lateral micro LED chip 300 joined to the chip joining part 121 such that the n-side electrode 304 and the p-side electrode 305 face the chip joining part 121. And, with respect to the lateral micro LED chip 300, each of the p-side electrodes 305 and each of the lower electrode branch line parts 1203 are electrically connected each other and the n-side electrode 304 and the branch line part 140a of the upper electrode 140 are electrically connected each other. Light from the lateral micro LED chip 300 is taken out to the side opposite to the substrate 110.

According to the eighth embodiment, the same advantages as the first embodiment can be obtained using the lateral micro LED chip 300.

### The Ninth Embodiment

### [Color Micro LED Display]

In the ninth embodiment, a passive matrix driving system color micro LED display is described.

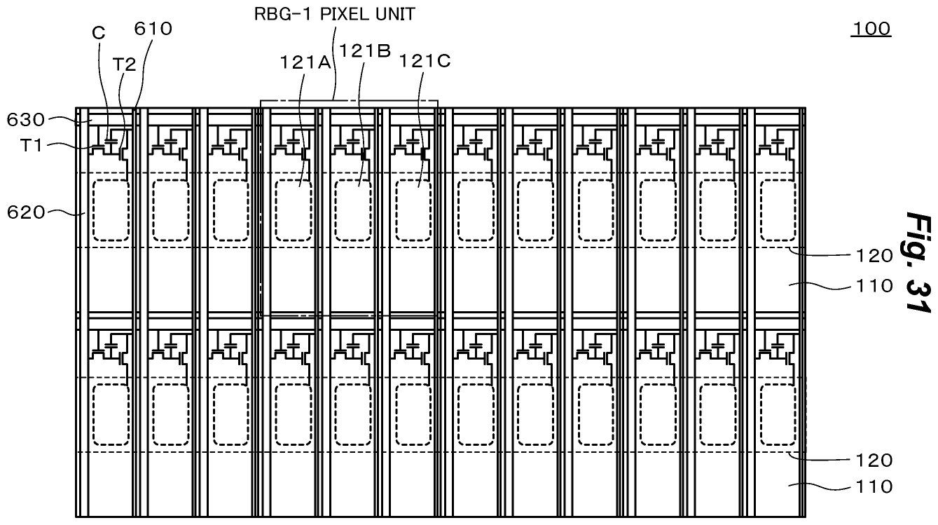

FIG. 29 shows the lower electrodes 120 on the mounting substrate 100 of the color micro LED display. As shown in FIG. 29, the lower electrodes 120 are formed parallel to each other in the row direction. RGB-1 pixel units, each of which is formed by arranging light emitting areas of each of RGB adjacently each other along each lower electrode 120 are arranged and as a whole of the mounting substrate 100 pixels are arranged in a two-dimensional matrix. In each pixel, three chip joining parts 121A, 121B, 121C are formed on the lower electrode 120 and they correspond to, for example, light emitting areas of each of B, R, G.

FIG. 30 shows the state where the vertical micro LED chips for light emission of each of RGB are mounted on the mounting substrate 100 as the same as the first embodiment and the upper electrode 140 is formed. More specifically, a blue light emission vertical micro LED chip 510 is joined to the chip joining part 121A, a red light emission vertical micro LED chip 520 is joined to the chip joining part 421B and a green light emission vertical micro LED chip 530 is joined to the chip joining part 421C. The upper electrode 140 is provided along the chip joining parts 121A in the column direction. Each of the upper electrode branch line parts 142 which is connected to the upper electrode main line part 141 of the upper electrode 140 via the thin film fuse 143 is connected to p-side electrodes of the vertical micro LED chip 510 on the chip joining part 421A, p-side electrodes of the vertical micro LED chip 520 on the chip joining part 421B and p-side electrodes of the vertical micro LED chip 530 on the chip joining part 421C. Selection of light emitting areas of each pixel is carried out by selection of the lower electrode 120 and the upper electrode 140. FIG. 30 shows one circuit unit.

The blue light emission vertical micro LED chip 510 and the green light emission vertical micro LED chip 530 have the same structure as the vertical micro LED chip 10 according to the first embodiment, though composition of their light emitting layers are different each other. The red light emission vertical micro LED chip 520 uses AlGaInP-based semiconductor and has the same structure as the vertical micro LED chip 10 according to the first embodiment.

According to the ninth embodiment, it is possible to mount the vertical micro LED chips for light emission of each of RGB on the mounting substrate 100 easily, efficiently and in a very short time and to remove effects of defective vertical micro LED chips easily, whereby a high performance passive driving system color micro LED display can be realized at low cost.

### The Tenth Embodiment

### [Color Micro LED Display]

In the tenth embodiment, an active matrix driving system color micro LED display is described.

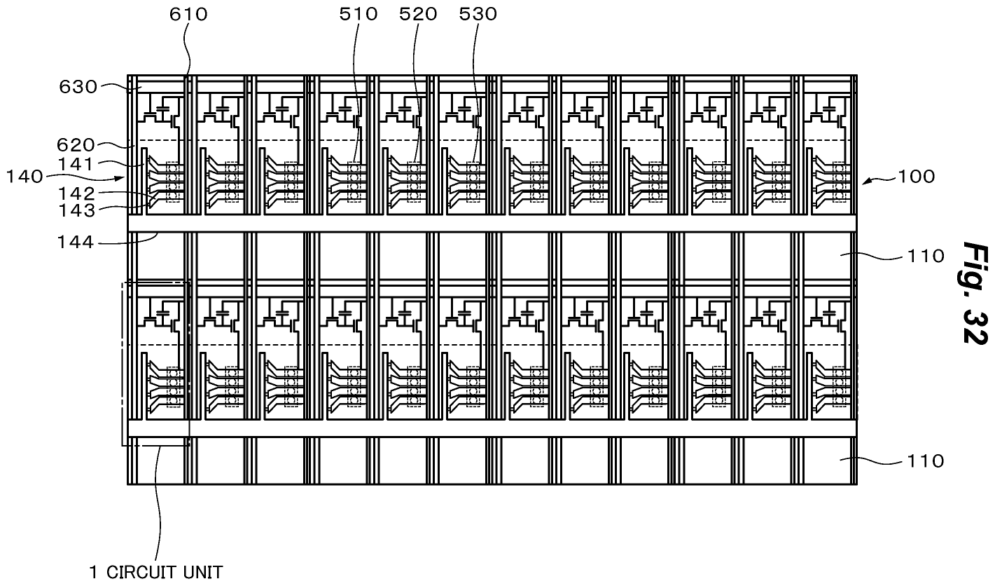

FIG. 31 shows lower electrode wiring lines on the mounting substrate 100 of the color micro LED display. The lower electrodes 120 of the lower electrode wiring lines are provided parallel to each other in the row direction as the same as the ninth embodiment. RGB-1 pixel units, each of which is formed by arranging light emitting areas of each of RGB adjacently each other along each lower electrode 120 are arranged and as a whole of the mounting substrate 100 pixels are arranged in a two-dimensional matrix. In each pixel, three chip joining parts 121A, 121B, 121C are formed on the lower electrode 120 and they correspond to, for example, light emitting areas of B, R, G, respectively. Provided also as the lower electrode wiring lines are power supplying lines 610 and data lines 620 which extend in the column direction and scanning lines 630 which extend in the row direction. An active driving circuit is provided between each data line 620 and each light emitting area of each pixel. Each light emitting area of each pixel is selected by the active driving circuit. The active driving circuit is configured by transistors T1, T2 and a condenser C. The transistors T1, T2 are generally configured by a thin film transistor which uses a semiconductor thin film such as a polycrystalline Si thin film and the like. The condenser C is configured by stacking a lower electrode, an insulating film and an upper electrode. Source, drain and gate of the transistor T1 are connected to the data line 620, gate of the transistor T2 and the scanning line 630, respectively. Source and drain of the transistor T2 are connected to the power supplying line 610 and the lower electrode 120, respectively. The condenser C is connected between drain of the transistor T1 and the power supplying line 610. Each light emitting area of each pixel is selected by selection of the scanning line 630 and the data line 620.

FIG. 32 shows the state where the blue light emission vertical micro LED chips 510, the red light emission vertical micro LED chips 520 and the green light emission vertical micro LED chips 530 are mounted on the mounting substrate 100 as the same as the ninth embodiment and the upper electrode 140 is formed. The upper electrode 140 has a common electrode part 144 which connects each upper electrode main line part 141. FIG. 32 shows one circuit unit. The number of the vertical micro LED chips in one circuit unit is typically not less than 3.

The blue light emission vertical micro LED chip 510, the red light emission vertical micro LED chip 520 and the green light emission vertical micro LED chip 530 are the same as those used in the ninth embodiment.

According to the tenth embodiment, it is possible to mount vertical micro LED chips for light emission of each of RGB on the mounting substrate 100 easily, efficiently and in a very short time and to remove effects of defective vertical micro LED chips easily, whereby a high performance active driving system color micro LED display can be realized at low cost.

### The Eleventh Embodiment

### [Method of Manufacturing the Micro LED Integrated Device]

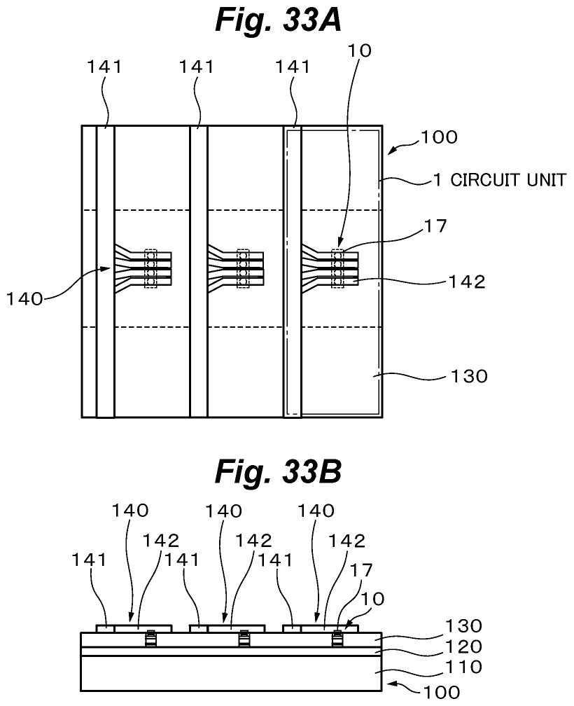

In the first embodiment, the upper electrode main line part 141 and the upper electrode branch line parts 142 are connected via the thin film fuse 143. The eleventh embodiment differs from the first embodiment in that the upper electrode main line part 141 and the upper electrode branch line parts 142 are directly connected as shown in FIG. 33A and FIG. 33B. In this case, a voltage is applied between the upper electrode 140 and the lower electrode 120 such that the potential of the lower electrode 120 is lower than that of the upper electrode 140 to make current of, for example, about 1 μA flow through the p-side electrodes 17 included in each vertical micro LED chip 10. And image analysis of emission of light of each vertical micro LED chip 10 is carried out to find the upper electrode branch line part 202 with defection of light quantity due to leakage defection of the vertical micro LED chip 10. Then, by cutting a part of the upper electrode branch line part 142 with defection of light quantity by laser beam irradiation and the like, the same result as cutting of the thin film fuse 143 is obtained. Others are the same as the first embodiment.

### [Micro LED Integrated Device]

The micro LED integrated device is the same as the first embodiment except that the upper electrode main line part 141 and the upper electrode branch line parts 142 are directly connected.

According to the eleventh embodiment, the same advantages as the first embodiment can be obtained.

Heretofore, embodiments of the present invention have been explained specifically. However, the present invention is not limited to these embodiments, but contemplates various changes and modifications based on the technical idea of the present invention.

For example, numerical numbers, structures, shapes, materials, methods and the like presented in the aforementioned embodiments are only examples, and the different numerical numbers, structures, shapes, materials, methods and the like may be used as necessary.

Although not illustrated as embodiments, RGB light emission may be realized by joining, for example, the blue light emission vertical micro LED chips 510 on all of three chip joining parts 121A, 121B, 121C and coating red phosphor and green phosphor over the chip joining parts 121B, 121C, respectively after formation of the upper electrode, test and repair. RGB light emission may be also realized by joining the blue light emission vertical micro LED chips 510 to the chip joining parts 121A, 121B and the green light emission vertical micro LED chip 130 to the chip joining part 121C and coating red phosphor over the chip joining part 421B after formation of the upper electrode, test and repair.

### EXPLANATION OF REFERENCE NUMERALS

10 vertical micro LED chip
11 n⁺-type semiconductor layer
12 light emitting layer
13 p-type semiconductor layer
14 n-side electrode
15 Sn film
16 insulating film
17 p-side electrode
100 mounting substrate
110 substrate
120 lower electrode
121 chip joining part
122 transparent electrode
130 insulating film
140 upper electrode
141 upper electrode main line part
142 upper electrode branch line part
143 thin film fuse
200 stamp
201 protrusion
300 lateral micro LED chip
301 n⁺-type semiconductor layer
302 light emitting layer
303 p-type semiconductor layer
314 n-side electrode
305 p-side electrode
1201,1202 lower electrode main line part
1203 lower electrode branch line part
1204 thin film fuse

1. A semiconductor light emitting element chip integrated device, comprising:
a substrate having a lower electrode on one major surface,
a chip joining part which is formed by a part of the upper surface or a protrusion or a concavity formed on a part of the upper surface of the lower electrode,
a vertical semiconductor light emitting element chip having a plurality of p-side electrodes and an n-side electrode on the upper surface and the lower surface joined to the chip joining part; and
an upper electrode as the upper layer of the semiconductor light emitting element chip having a main line part and a plurality of branch line parts which are connected each other by a thin film fuse or directly connected each other,
the semiconductor light emitting element chip being joined to the chip joining part such that the n-side electrode faces the chip joining part, the n-side electrode and the lower electrode being electrically connected each other and at least one of the p-side electrodes of the semiconductor light emitting element chip and the branch line parts of the upper electrode being electrically connected each other.

2. The semiconductor light emitting element chip integrated device according to claim 1 wherein each of the p-side electrodes and the branch line parts of the upper electrode is made of a transparent electrode and light emitted from the semiconductor light emitting element chip is transmitted through the p-side electrodes and the branch line parts of the upper electrode and taken out.

3. The semiconductor light emitting element chip integrated device according to claim 1 wherein each of the n-side electrode and apart of the lower electrode corresponding to the chip joining part is made of a transparent electrode and the substrate is transparent and light emitted from the semiconductor light emitting element chip is transmitted through the n-side electrode, the part of the lower electrode corresponding to the chip joining part and the substrate and taken out.

4. A semiconductor light emitting element chip integrated device, comprising:
a substrate having a lower electrode having a main line part and a plurality of branch line parts which are connected each other by a thin film fuse on one major surface,
a chip joining part which is formed by an area including at least a part of the upper surface of each of the branch line parts of the lower electrode,
a vertical semiconductor light emitting element chip having a plurality of p-side electrodes and an n-side electrode on the upper surface and the lower surface joined to the chip joining part; and
an upper electrode as the upper layer of the semiconductor light emitting element chip,
the semiconductor light emitting element chip being joined to the chip joining part such that the p-side electrodes face the chip joining part, at least one of the p-side electrodes and the branch line parts of the lower electrode being electrically connected each other and the n-side electrode of the semiconductor light emitting element chip and the upper electrode being electrically connected each other.

5. The semiconductor light emitting element chip integrated device according to claim 4 wherein each of the n-side electrode and at least a part of the upper electrode which extends over the semiconductor light emitting element chip is made of a transparent electrode and light emitted from the semiconductor light emitting element chip is transmitted through the n-side electrode and the part of the upper electrode which extends over the semiconductor light emitting element chip and taken out.

6. The semiconductor light emitting element chip integrated device according to claim 4 wherein each of the p-side electrodes and the branch line parts of the lower electrode is made of a transparent electrode and the substrate is transparent and light emitted from the semiconductor light emitting element chip is transmitted through the p-side electrodes, the branch line parts of the lower electrode and the substrate and taken out.

7. A semiconductor light emitting element chip integrated device, comprising:
a substrate having a lower electrode having a main line part and a plurality of branch line parts which are connected each other by a thin film fuse on one major surface,
an upper electrode as the upper layer of the lower electrode,
a chip joining part which is formed by an area including at least a part of the upper surface of each of the branch line parts of the lower electrode and a part of the upper surface of the upper electrode; and
a lateral semiconductor light emitting element chip having a plurality of p-side electrodes and an n-side electrode on one surface joined to the chip joining part,
the semiconductor light emitting element chip being joined to the chip joining part such that the p-side electrodes and the n-side electrode face the chip joining part, at least one of the p-side electrodes and the branch line parts of the lower electrode being electrically connected each other and the n-side electrode of the semiconductor light emitting element chip and the upper electrode being electrically connected each other.

8. The semiconductor light emitting element chip integrated device according to claim 7 wherein light emitted from the semiconductor light emitting element chip is taken out to the side opposite to the substrate.

9. The semiconductor light emitting element chip integrated device according to claim 7 wherein each of the p-side electrodes and the branch line parts of the lower electrode is made of a transparent electrode and the substrate is transparent and light emitted from the semiconductor light emitting element chip is transmitted through the p-side electrodes, the branch line parts of the lower electrode and the substrate and taken out.

10. A semiconductor light emitting element chip integrated device, comprising:
a substrate having a lower electrode on one major surface,
an upper electrode as the upper layer of the lower electrode having a main line part and a plurality of branch line parts which are connected each other by a thin film fuse or directly connected each other,
a chip joining part which is formed by an area including at least a part of the upper surface of the lower electrode and at least a part of the upper surface of each of the branch line parts of the upper electrode; and
a lateral semiconductor light emitting element chip having a plurality of p-side electrodes and an n-side electrode on one surface joined to the chip joining part,
the semiconductor light emitting element chip being joined to the chip joining part such that the p-side electrodes and the n-side electrode face the chip joining part, at least one of the p-side electrodes and the branch line parts of the upper electrode being electrically connected each other and the n-side electrode of the semiconductor light emitting element chip and the lower electrode being electrically connected each other.

11. A method of manufacturing a semiconductor light emitting element chip integrated device, comprising steps of:
joining a vertical semiconductor light emitting element chip having a plurality of p-side electrodes and an n-side electrode on the upper surface and the lower surface to a chip joining part which is formed by a part of the upper surface or a protrusion or a concavity formed on a part of the upper surface of a lower electrode of a substrate having the lower electrode on one major surface such that the n-side electrode faces the chip joining part and electrically connecting the n-side electrode and the lower electrode each other; and
forming an upper electrode as the upper layer of the semiconductor light emitting element chip having a main line part and a plurality of branch line parts which are connected each other by a thin film fuse or directly connected each other such that at least one of the p-side electrodes of the semiconductor light emitting element chip and the branch line parts of the upper electrode is electrically connected each other.

12. The method of manufacturing a semiconductor light emitting element chip integrated device according to claim 11 further comprising a step of making flow current by applying a voltage for repair between the branch line parts and the main line part after the upper electrode is formed.

13. The method of manufacturing a semiconductor light emitting element chip integrated device according to claim 11 wherein the semiconductor light emitting element chip is joined to the chip joining part by multichip transfer methods.

14. A method of manufacturing a semiconductor light emitting element chip integrated device, comprising steps of:
joining a vertical semiconductor light emitting element chip having a plurality of p-side electrodes and an n-side electrode on the upper surface and the lower surface to a chip joining part which is formed by an area including at least a part of the upper surface of each of branch line parts of a lower electrode of a substrate having a main line part and a plurality of branch line parts which are connected each other by a thin film fuse on one major surface such that the p-side electrodes face the chip joining part and electrically connecting at least one of the p-side electrodes and the branch line parts of the lower electrode each other; and
forming an upper electrode as the upper layer of the semiconductor light emitting element chip such that the n-side electrode of the semiconductor light emitting element chip and the upper electrode are electrically connected each other.

15. The method of manufacturing a semiconductor light emitting element chip integrated device according to claim 14 further comprising a step of making flow current by applying a voltage for repair between the branch line parts and the main line part after the upper electrode is formed.

16. The method of manufacturing a semiconductor light emitting element chip integrated device according to claim 14 wherein the semiconductor light emitting element chip is joined to the chip joining part by multichip transfer methods.

17. A method of manufacturing a semiconductor light emitting element chip integrated device, comprising steps of:
forming a lower electrode having a main line part and a plurality of branch line parts which are connected each other by a thin film fuse and an upper electrode as the upper layer of the lower electrode on one major surface of a substrate; and
joining a lateral semiconductor light emitting element chip having a plurality of p-side electrodes and an n-side electrode on one surface to a chip joining part which is formed by an area including at least apart of the upper surface of each of the branch line parts of the lower electrode and a part of the upper surface of the upper electrode such that the p-side electrodes and the n-side electrode face the chip joining part, electrically connecting at least one of the p-side electrodes and the branch line parts of the lower electrode each other and electrically connecting the n-side electrode and the upper electrode each other.

18. The method of manufacturing a semiconductor light emitting element chip integrated device according to claim 17 further comprising a step of making flow current by applying a voltage for repair between the branch line parts and the main line part after the semiconductor light emitting element chip is joined to the chip joining part, at least one of the p-side electrodes and the branch line part of the lower electrode are electrically connected and the n-side electrode and the upper electrode are electrically connected.

19. The method of manufacturing a semiconductor light emitting element chip integrated device according to claim 17 wherein the semiconductor light emitting element chip is joined to the chip joining part by multi-chip transfer methods.

20. A method of manufacturing a semiconductor light emitting element chip integrated device, comprising steps of:
forming a lower electrode and an upper electrode as the upper layer of the lower electrode having a main line part and a plurality of branch line parts which are connected each other by a thin film fuse or directly connected on one major surface of a substrate,
joining a lateral semiconductor light emitting element chip having a plurality of p-side electrodes and an n-side electrode on one surface to a chip joining part which is formed by an area including a part of the upper surface of the lower electrode and at least a part of the upper surface of each of the branch line parts of the upper electrode such that the p-side electrodes and the n-side electrode face the chip joining part, electrically connecting the n-side electrode and the lower electrode each other and electrically connecting at least one of the p-side electrodes and the branch line parts of the upper electrode each other.
